(19) United States
(12) Patent Application Publication
(10) Pub. No.: US 2018/0330933 A1
(43) Pub. Date: Nov. 15, 2018

(54) COOLING DEVICES AND INSTRUMENTS INCLUDING THEM

(71) Applicants: Brian Chan, Markham (CA); James E Botelho, Danbury, CT (US); Peter J Morrisroe, New Milford, CT (US)

(72) Inventors: Brian Chan, Markham (CA); James E Botelho, Danbury, CT (US); Peter J Morrisroe, New Milford, CT (US)

(21) Appl. No.: 15/940,077

(22) Filed: Mar. 29, 2018

Related U.S. Application Data
(60) Provisional application No. 62/478,348, filed on Mar. 29, 2017.

(51) Int. Cl. H01J 49/04; H01J 49/36; F28D 15/02

(52) U.S. Cl. CPC H01J 49/0468; H05K 7/20336; F28D 15/0266; H01J 49/36

(57) ABSTRACT

Certain configurations are described herein of an instrument comprising a passive cooling device which includes, in part, a loop thermosyphon configured to thermally couple to a component of the instrument to be cooled. In some instances, the cooling device can cool a transistor, transistor pair, an interface or other components of the instrument.

### PRIORITY APPLICATION

This application is related to and claims priority to and the benefit of U.S. Provisional Application No. 62/478,348 filed on Mar. 29, 2017, the entire disclosure of which is hereby incorporated herein by reference.

### TECHNOLOGICAL FIELD

This application is directed to cooling devices and instruments including them. More particularly, certain configurations described herein are directed to an instrument comprising a passive cooling device which includes, in part, a loop thermosyphon configured to thermally couple to a component of the instrument to be cooled.

### BACKGROUND

Instruments are used in chemical and clinical analysis to identify analyte components present in a mixture. The instruments typically include one or more detectors which can detect the analyte components.

### SUMMARY

Certain illustrative configurations of cooling devices and instruments that include them are described in more detail below. While not every possible type of instrument is described, chemical analysis instruments and/or clinical instruments, for example, which comprise one or more components to be cooled can be used with the passive cooling devices described herein.

In one aspect, an instrument comprises an analyte introduction stage. In other instances, the instrument may also comprise one or more of an analyte preparation stage and an analyte detection stage. For example, the instrument may comprise an analyte preparation stage fluidically coupled to the analyte introduction stage and configured to receive analyte from the analyte introduction stage. The instrument may comprise an analyte detection stage fluidically coupled to the analyte preparation stage and configured to receive analyte from the analyte preparation stage, in which at least one of the analyte introduction stage, the analyte preparation stage and the analyte detection stage comprises a loop thermosyphon thermally coupled to a component in one of the analyte introduction stage, the analyte preparation stage and the analyte detection stage.

In certain configurations, the analyte introduction stage comprises one of a nebulizer, an injector and an atomizer. In other instances, the analyte preparation stage comprises one of a plasma, a flame, an arc, and a spark. In some embodiments, the analyte preparation stage comprises a torch, an induction device and a radio frequency generator electrically coupled to the induction device, in which the torch is configured to receive a section of the induction device and provide radio frequency energy into the section of the torch to sustain a plasma in the section of the torch, in which the loop thermosyphon is thermally coupled to a transistor or a transistor pair of the radio frequency generator. In other examples, the analyte detection stage comprises a mass analyzer fluidically coupled to a detector. In certain instances, the instrument comprises an interface between the analyte preparation stage and the mass analyzer, in which the interface is thermally coupled to the loop thermosyphon. In some examples, the instrument comprises an interface between the analyte preparation stage and the mass analyzer, in which the loop thermosyphon is integral to the interface. In other examples, the loop thermosyphon thermally couples to the interface through a first plate and a second plate. In certain examples, the second plate comprises a groove to receive an evaporator loop of the loop thermosyphon and the first plate couples to the second plate to sandwich the evaporator loop between the first plate and the second plate, wherein the second plate couples to the interface.

In some embodiments, the instrument further comprises a second loop thermosyphon thermally coupled to at least one of the analyte introduction stage, the analyte preparation stage and the analyte detection stage, wherein the loop thermosyphon is thermally coupled to a different stage than the second loop thermosyphon. In certain examples, the analyte preparation stage comprises a torch, an induction device and a radio frequency generator electrically coupled to the induction device, in which the torch is configured to receive a section of the induction device and provide radio frequency energy into the section of the torch to sustain a plasma in the section of the torch, in which the loop thermosyphon is thermally coupled to a transistor or a transistor pair of the radio frequency generator, and in which the second loop thermosyphon is thermally coupled to a pump present in the analyte detection stage. In some instances, the analyte preparation stage comprises a torch, an induction device and a radio frequency generator electrically coupled to the induction device, in which the torch is configured to receive a section of the induction device and provide radio frequency energy into the section of the torch to sustain a plasma in the section of the torch, in which the loop thermosyphon is thermally coupled to a transistor or a transistor pair of the radio frequency generator, and in which the second loop thermosyphon is thermally coupled to an interface present between the torch and the analyte detection stage. In certain examples, the second loop thermosyphon thermally couples to the interface through a first plate and a second plate. In further embodiments, the second plate comprises a groove to receive an evaporator loop of the loop thermosyphon and the first plate couples to the second plate to sandwich the evaporator loop between the first plate and the second plate, wherein the second plate couples to the interface. In some configurations, the analyte introduction stage comprises a nebulizer, the analyte preparation stage comprises a torch, an induction device and a radio frequency generator electrically coupled to the induction device, in which the torch is configured to receive a section of the induction device and provide radio frequency energy into the section of the torch to sustain a plasma in the section of the torch, in which the loop thermosyphon is thermally coupled to a transistor or a transistor pair of the radio frequency generator, in which the nebulizer is fluidically coupled to the torch, in which the analyte detection stage comprises a mass spectrometer, in which the mass spectrometer is fluidically coupled to the torch, and wherein the second loop thermosyphon is thermally coupled to a pump present in the mass spectrometer.

In other configurations, the instrument further comprises a third loop thermosyphon thermally coupled to at least one of the analyte introduction stage, the analyte preparation stage and the analyte detection stage. In some embodiments, the third loop thermosyphon is thermally coupled to a same stage as the first loop thermosyphon or the second look thermosyphon. In certain examples, the second loop thermosyphon thermally couples to the interface through a first plate and a second plate. In some instances, the analyte introduction stage comprises a nebulizer, the analyte preparation stage comprises a torch, an induction device and a radio frequency generator electrically coupled to the induction device, in which the torch is configured to receive a section of the induction device and provide radio frequency energy into the section of the torch to sustain a plasma in the section of the torch, in which the loop thermosyphon is thermally coupled to a transistor or a transistor pair of the radio frequency generator, in which the nebulizer is fluidically coupled to the torch, in which the analyte detection stage comprises a mass spectrometer, in which the mass spectrometer is fluidically coupled to the torch, and wherein the second loop thermosyphon is thermally coupled to a pump present in the mass spectrometer. In other examples, the analyte introduction stage comprises a nebulizer, the analyte preparation stage comprises a torch, an induction device and a radio frequency generator electrically coupled to the induction device, in which the torch is configured to receive a section of the induction device and provide radio frequency energy into the section of the torch to sustain a plasma in the section of the torch, in which the loop thermosyphon is thermally coupled to a transistor or a transistor pair of the radio frequency generator, in which the nebulizer is fluidically coupled to the torch, in which the analyte detection stage comprises a mass spectrometer, in which the mass spectrometer is fluidically coupled to the torch through an interface, wherein the second loop thermosyphon is thermally coupled to a pump present in the mass spectrometer, and wherein the third loop thermosyphon is thermally coupled to the interface.

In another aspect, an instrument comprises an interface thermally coupled to a passive cooling device. For example, the instrument may comprise an atomization device configured to sustain an atomization source. The instrument may also comprise an induction device configured to receive a portion of the atomization device to provide radio frequency energy into the received portion of the atomization device. The instrument may comprise a radio frequency generator electrically coupled to the induction device. The instrument may also comprise an interface fluidically coupled to the atomization device, in which the interface is thermally coupled to a passive cooling device. The instrument may further comprise a detector fluidically coupled to the interface.

In certain configurations, the instrument does not include a chiller configured to cool the interface. In other configurations, the passive cooling device is configured as a loop thermosyphon. In some examples, the loop thermosyphon comprises a closed loop heat pipe. In certain instances, the loop thermosyphon comprises an evaporator fluidically coupled to a condenser through a downcomer fluid line and fluidically coupled to the condenser through an upcomer fluid line. In some examples, the condenser is positioned external to a housing comprising the atomization device and the interface. In other examples, the evaporator is coupled to the interface with at least one plate. In some embodiments, the passive cooling device is further thermally coupled to a transistor of the radio frequency generator and is configured to simultaneously cool the interface and the transistor.

In other embodiments, the instrument comprises a second passive cooling device thermally coupled to a transistor of the radio frequency generator. In some instances, the second passive cooling device is configured as a second loop thermosyphon. In other examples, the second loop thermosyphon comprises an evaporator fluidically coupled to a condenser through a downcomer fluid line and fluidically coupled to the condenser through an upcomer fluid line. In some embodiments, the passive cooling device is further configured to provide heat to the interface to pre-heat the interface. In other embodiments, the passive cooling device comprises a plate configured to sandwich the evaporator to the interface to increase surface area contact between an evaporator loop of the cooling device and the interface. In certain instances, the passive cooling device is configured as a loop thermosyphon, in which the evaporator loop is sandwiched between the plate and a second plate comprising a groove to receive the evaporator loop, in which the second plate is coupled to the interface, and in which the evaporator loop, the plate and the second plate are coupled to each other through a solder joint. In other embodiments, the atomization device is configured to sustain an inductively coupled plasma. In some examples, the induction device comprises an induction coil comprising at least one radial fin. In other examples, the detector is a mass spectrometer. In some examples, the detector is an optical detector. In other examples, the atomization device is configured to sustain a flame. In some configurations, the atomization device is configured to sustain an inductively coupled plasma, the induction device comprises an induction coil comprising at least one radial fin, and the passive cooling device comprises a loop thermosyphon comprising an evaporator fluidically coupled to a condenser through a downcomer fluid line and fluidically coupled to the condenser through an upcomer fluid line, in which the evaporator of the loop thermosyphon is thermally coupled to the interface.

In an additional aspect, an instrument comprises an interface comprising an integral passive cooling device. For example, the instrument may comprise an atomization device configured to sustain an atomization source, an induction device configured to receive a portion of the atomization device to provide radio frequency energy into the received portion of the atomization device, a radio frequency generator electrically coupled to the induction device, and an interface fluidically coupled to the atomization device, in which the interface comprises an integral passive cooling device. In some instances, the instrument may also comprise a detector fluidically coupled to the interface.

In certain embodiments, the instrument does not include a chiller configured to cool the interface. In other embodiments, the passive cooling device is configured as a loop thermosyphon. In some examples, the loop thermosyphon comprises a closed loop heat pipe. In certain instances, the loop thermosyphon comprises an evaporator fluidically coupled to a condenser through a downcomer fluid line and fluidically coupled to the condenser through an upcomer fluid line. In some embodiments, the condenser is positioned external to a housing comprising the atomization device and the interface. In other examples, the evaporator is integral to the interface and the condenser is separated from the evaporator by the downcomer fluid line and the upcomer fluid line. In certain examples, the passive cooling device is further thermally coupled to the transistor of the radio frequency generator and is configured to simultaneously cool the interface and the transistor.

In other examples, the instrument comprises a second passive cooling device thermally coupled to a transistor of the radio frequency generator. In some embodiments, the second passive cooling device is configured as a second loop thermosyphon. In other embodiments, the second loop thermosyphon comprises an evaporator fluidically coupled to a condenser through a downcomer fluid line and fluidically coupled to the condenser through an upcomer fluid line.

In some embodiments, the passive cooling device is configured as a loop thermosyphon, in which an evaporator loop of the loop thermosyphon is sandwiched between the plate and interface, and in which the evaporator loop, the plate and the interface are coupled to each other through a solder joint. In other examples, the loop thermosyphon comprises an air cooled condenser. In some instances, the integral passive cooling device is further configured to provide heat to the interface to pre-heat the interface.

In other examples, the atomization device is configured to sustain an inductively coupled plasma. In some embodiments, the induction device comprises an induction coil comprising at least one radial fin. In certain examples, the detector is a mass spectrometer. In some examples, the detector is an optical detector. In other examples, the atomization device is configured to sustain a flame. In some embodiments, the atomization device is configured to sustain an inductively coupled plasma, the induction device comprises an induction coil comprising at least one radial fin, and the integral passive cooling device comprises a loop thermosyphon comprising an evaporator fluidically coupled to a condenser through a downcomer fluid line and fluidically coupled to the condenser through an upcomer fluid line, in which the evaporator of the loop thermosyphon is integral to the interface.

In another aspect, an instrument may comprise a radio frequency generator electrically comprising a transistor or a transistor pair thermally coupled to a passive cooling device. For example, an instrument may comprise an atomization device configured to sustain an atomization source, an induction device configured to receive a portion of the atomization device to provide radio frequency energy into the received portion of the atomization device, a radio frequency generator electrically coupled to the induction device, in which the generator comprises a transistor or a transistor pair thermally coupled to a passive cooling device. If desired, the instrument may also comprise a detector fluidically coupled to the atomization device.

In certain instances, the instrument does not include a chiller configured to cool the transistor or the transistor pair. In other examples, the passive cooling device is configured as a loop thermosyphon. In some configurations, the loop thermosyphon comprises a closed loop heat pipe. In additional configurations, the loop thermosyphon comprises an evaporator fluidically coupled to a condenser through a downcomer fluid line and fluidically coupled to the condenser through an upcomer fluid line. In some embodiments, the condenser is positioned external to a housing comprising the atomization device and the radio frequency generator. In other embodiments, the evaporator is coupled to the transistor or the transistor pair through at least one plate. In certain instances, the passive cooling device is further thermally coupled to an interface of the instrument.

In some embodiments, the instrument comprises a second passive cooling device thermally coupled to at least one of the induction device and the detector. In other examples, the second passive cooling device is configured as a second loop thermosyphon. In certain embodiments, the second loop thermosyphon comprises an evaporator fluidically coupled to a condenser through a downcomer fluid line and fluidically coupled to the condenser through an upcomer fluid line.

In some examples, the passive cooling device is further configured to provide heat to the transistor or the transistor pair. In certain instances, the passive cooling device comprises a plate configured to sandwich the evaporator to the transistor or the transistor pair to increase surface area contact between an evaporator loop of the cooling device and the transistor or the transistor pair. In other examples, the passive cooling device is configured as a loop thermosyphon, in which the evaporator loop is sandwiched between the plate and a second plate comprising a groove to receive the evaporator loop, in which the second plate is thermally coupled to the transistor or the transistor pair, and in which the evaporator loop, the plate and the second plate are coupled to each other through a solder joint.

In some configurations, the atomization device is configured to sustain an inductively coupled plasma. In other configurations, the induction device comprises an induction coil comprising at least one radial fin. In some embodiments, the detector is a mass spectrometer. In certain examples, the detector is an optical detector. In other examples, the atomization device is configured to sustain a flame. In some embodiments, the atomization device is configured to sustain an inductively coupled plasma, the induction device comprises an induction coil comprising at least one radial fin, and the passive cooling device comprises a loop thermosyphon comprising an evaporator fluidically coupled to a condenser through a downcomer fluid line and fluidically coupled to the condenser through an upcomer fluid line, in which the evaporator of the loop thermosyphon is thermally coupled to the transistor or the transistor pair.

In another aspect, a system may comprise an interface thermally coupled to a passive cooling device comprising a loop thermosyphon configured to cool the interface. For example, the system may be configured to sustain an inductively coupled plasma and comprise an interface fluidically coupled to a torch configured to sustain a plasma in a section of the torch using an induction device, in which the interface is thermally coupled to a passive cooling device comprising a loop thermosyphon configured to cool the interface.

In certain configurations, the loop thermosyphon is configured as a closed loop heat pipe. In other configurations, the loop thermosyphon comprises an evaporator configured to thermally couple to the interface. In some examples, the evaporator is fluidically coupled to a condenser through a downcomer fluid line and fluidically coupled to the condenser through an upcomer line. In certain embodiments, the induction device comprises one of an induction coil comprising a radial fin, an induction coil and a plate electrode. In other examples, the system further comprises a radio frequency generator comprising a transistor or a transistor pair, in which the radio frequency generator is electrically coupled to the induction device.

In some instances, the system further comprises a second passive cooling device thermally coupled to the transistor or the transistor pair of the radio frequency generator. In other embodiments, the second passive cooling device is configured as a loop thermosyphon. In certain examples, the loop thermosyphon of the second passive cooling device comprises an evaporator fluidically coupled to a condenser through a downcomer fluid line and fluidically coupled to the condenser through an upcomer fluid line. In some embodiments, the system does not include a chiller configured to cool the interface.

In an additional aspect, a system may comprise a radio frequency generator comprising at least one transistor or transistor pair thermally coupled to a passive cooling device configured to cool the transistor or transistor pair. For example, the system may be configured to sustain a plasma and comprise a torch configured to sustain the plasma, an induction device configured to receive a portion of the torch to provide radio frequency energy to the received portion of the torch, and a radio frequency generator electrically coupled to the induction device, in which at least one transistor or transistor pair of the radio frequency generator is thermally coupled to a passive cooling device configured to cool the transistor or the transistor pair.

In certain configurations, the passive cooling device is configured as a loop thermosyphon. In other configurations, the loop thermosyphon comprises a closed loop heat pipe. In further examples, the loop thermosyphon comprises an evaporator fluidically coupled to a condenser through a downcomer fluid line and fluidically coupled to the condenser through an upcomer fluid line. In some embodiments, the condenser is positioned at a higher height than the evaporator. In certain examples, the induction device comprises one of an induction coil comprising a radial fin, an induction coil and a plate electrode.

In other examples, the system comprises a second passive cooling device configured to thermally couple to the induction device or the torch. In some examples, the second passive cooling device is configured as a loop thermosyphon. In other examples, the loop thermosyphon of the second passive cooling device comprises an evaporator fluidically coupled to a condenser through a downcomer fluid line and fluidically coupled to the condenser through an upcomer fluid line. In some embodiments, the system does not include a chiller configured to cool the transistor or the transistor pair.

In some examples, a method of cooling an interface in a system comprises passively removing heat from the interface using a loop thermosyphon thermally coupled to the interface. In some examples, the method comprises configuring the loop thermosyphon with an evaporator fluidically coupled to a condenser through a downcomer fluid line and fluidically coupled to the condenser through an upcomer fluid line. In other examples, the method comprises simultaneously cooling a transistor of a radio frequency generator electrically coupled to an induction device of the system. In further examples, the method comprises operating the system without the use of a shear gas to terminate the plasma. In some embodiments, the method comprises configuring the loop thermosyphon with a heat pipe. In certain instances, the method comprises configuring the system with a fan to provide air to the loop thermosyphon. In other examples, the method comprises configuring the loop thermosyphon to be partially external to a housing of the system. In certain instances, the method comprises configuring the system with a mass spectrometer fluidically coupled to the interface. In some examples, the method comprises configuring the system with an optical detector. In some embodiments, the method comprises operating the plasma without using a chiller to cool the interface.

In another aspect, a method of cooling a transistor or a transistor pair of a radio frequency generator electrically coupled to an induction device of a system comprises passively removing heat from the transistor using a loop thermosyphon thermally coupled to the transistor or the transistor pair. In some examples, the method comprises configuring the loop thermosyphon with an evaporator fluidically coupled to a condenser through a downcomer fluid line and fluidically coupled to the condenser through an upcomer fluid line. In some examples, the method comprises simultaneously cooling an interface fluidically coupled to the plasma. In other examples, the method comprises operating the system without the use of a shear gas to terminate the plasma. In certain embodiments, the method comprises configuring the loop thermosyphon with a heat pipe. In some examples, the method comprises configuring the system with a fan to provide air to the loop thermosyphon. In certain instances, the method comprises configuring the loop thermosyphon to be partially external to a housing of the system. In some embodiments, the method comprises configuring the system with a mass spectrometer fluidically coupled to the plasma. In certain examples, the method comprises configuring the system with an optical detector. In some instances, the method comprises operating the plasma without using a chiller to cool the transistor or the transistor pair.

In another aspect, a system constructed and arranged to sustain a plasma using an induction device configured to provide radio frequency energy into a torch to sustain the plasma comprises an interface configured to fluidically couple to the sustained plasma and receive species from the sustained plasma, the interface thermally coupled to a loop thermosyphon configured to cool the interface.

In an additional aspect, a system constructed and arranged to sustain a plasma using an induction device configured to provide radio frequency energy into a torch to sustain the plasma comprises an interface configured to fluidically couple to the sustained plasma and receive species from the sustained plasma, the interface comprising a loop thermosyphon configured to cool the interface.

In another aspect, a system constructed and arranged to sustain a plasma using an induction device configured to provide radio frequency energy into a torch to sustain the plasma comprises a radio frequency generator configured to electrically couple to the induction device, the radio frequency generator comprising at least one transistor or transistor pair thermally coupled to a loop thermosyphon configured to cool the transistor of the transistor pair.

In an additional aspect, a kit comprising a loop thermosyphon constructed and arranged to thermally couple to an interface of an instrument to cool the interface during operation of the instrument is provided. In some instances, the kit also comprises a first plate configured to couple to the loop thermosyphon and the interface. In other instances, the kit also comprises a second plate configured to couple to the loop thermosyphon and the second plate to sandwich an evaporator loop of the loop thermosyphon between the first and second plates.

In another aspect, a kit comprising a loop thermosyphon integral to an interface of an instrument, in which the loop thermosyphon is configured to cool the interface during operation of the instrument is described.

In an additional aspect, a kit comprising a loop thermosyphon constructed and arranged to thermally couple to a transistor or a transistor pair of a radio frequency generator of an instrument to cool the transistor or the transistor pair during operation of the instrument is provided.

Additional aspects, features, examples and embodiments are described in more detail below.

### BRIEF DESCRIPTION OF THE SEVERAL VIEWS OF THE DRAWINGS

Certain configurations of cooling devices and instruments and other devices which include them are described below with reference to the accompanying figures in which:

FIG. 1 is an illustration of an instrument, in accordance with certain configurations;

FIGS. 2A-2G are illustrations of instruments with one or more cooling devices, in accordance with certain examples;

FIG. 3 is an illustration of an instrument comprising an interface, in accordance with some embodiments;

FIG. 4 is an illustration of a cooling device configured as a loop thermosyphon, in accordance with certain examples;

FIG. 5 is an illustration of a loop thermosyphon comprising a plate evaporator, in accordance with certain embodiments;

FIG. 6 is an illustration of an evaporator loop of a loop thermosyphon coupled to a plate, in accordance with certain configurations;

FIG. 7 is an illustration of a condenser of a loop thermosyphon, in accordance with certain examples;

FIG. 8 is a block diagram of an instrument comprising an interface, in accordance with certain embodiments;

FIGS. 9A-9C are illustration of various induction devices and torches, in accordance with certain examples;

FIG. 10 is a block diagram of a system comprising a radio frequency generator, in accordance with certain configurations;

FIG. 11 is an illustration of a mass spectrometer, in accordance with certain examples;

FIG. 12 is an illustration of an instrument comprising an optical detector, in accordance with certain examples;

FIG. 13 is another illustration of an instrument comprising an optical detector, in accordance with certain examples;

FIG. 14 is an illustration of a loop thermosyphon, in accordance with certain embodiments;

FIG. 15 is a graph showing the test results of the length of the evaporator, in accordance with certain examples;

FIG. 16 is an illustration of an interface comprising a loop thermosyphon, in accordance with certain configurations;

FIG. 17 is an illustration of a plate, in accordance with certain examples;

FIG. 18 is an illustration of an interface comprising a loop thermosyphon, in accordance with certain examples;

FIG. 19 is a graph showing signal stability in the absence of heating using cartridge heaters thermally coupled to the interface; and

FIG. 20 is a graph showing signal stability in the presence of heating using the cartridge heaters thermally coupled to the interface.

It will be recognized by the person of ordinary skill in the art, given the benefit of this disclosure, that the lengths and dimensions of the loop thermosyphon components in the figures are not necessarily drawn to scale. The dimensions of the condenser, the evaporator loop length and the downcomer and upcomer fluid line lengths may vary depending on the exact cooling desired and the configuration of the loop thermosyphon.

### DETAILED DESCRIPTION

Various components are described below in connection with instruments and cooling devices. It will be recognized by the person of ordinary skill in the art, given the benefit of this disclosure, that other components can be included in the instruments or cooling devices or certain components or portions of an instrument or a cooling device can be omitted while still providing a functional device. For ease of illustration and to facilitate a better understanding of the technology, not every component of a particular instrument is shown or described. In some examples other components or other types of components can also be present. For example, charge-coupled detectors, complimentary metal-oxide-semiconductor detectors or other detectors can be used and, if desired, can be cooled using the devices described herein.

While various aspects and configurations are described in reference to a cooling device, if desired, one or more heating devices or heating modules can be thermally coupled to any one or more of the components described herein to assist in temperature control or selection. Further, heat shielding, heat reflection or other heating means and heating dissipation means may also be present on any one or more of the components or stages described herein. If desired, the heating device can be present in addition to the cooling device or as noted below the cooling device itself can be used to provide heat to one or more components. The exact power of any heating device may vary from about 50 Watts to about 200 Watts, e.g., about 100 Watts and other suitable powers can also be used.

In certain configurations, the cooling devices described herein may comprise an interface configured to thermally couple the cooling device to one or more components of an instrument to be cooled. The particular component or components to be cooled can vary from instrument to instrument, and typical components to be cooled include, for example, transistors on printed circuit boards present in high voltage radio frequency generators, induction devices present in plasma based instruments, pumps of spectrometry instruments such as mass spectrometers, interfaces between various components of the system and other electrical or physical components. In many conventional instruments, a liquid cold plate which includes a cooling fluid circulated to and from a chiller is present and used to cool the devices. This type of cooler has several disadvantages including the need for the chiller, the possibility of cooling fluid leakage in the instrument and the additional power requirements needed to cool and circulate the cooling fluid. In some instances herein, the cooling devices described herein can be configured to provide cooling without the use of any chiller to circulate liquid through a liquid cold plate. The omission of the chiller reduces the overall size of the instrument and simplifies cooling of the instrument.

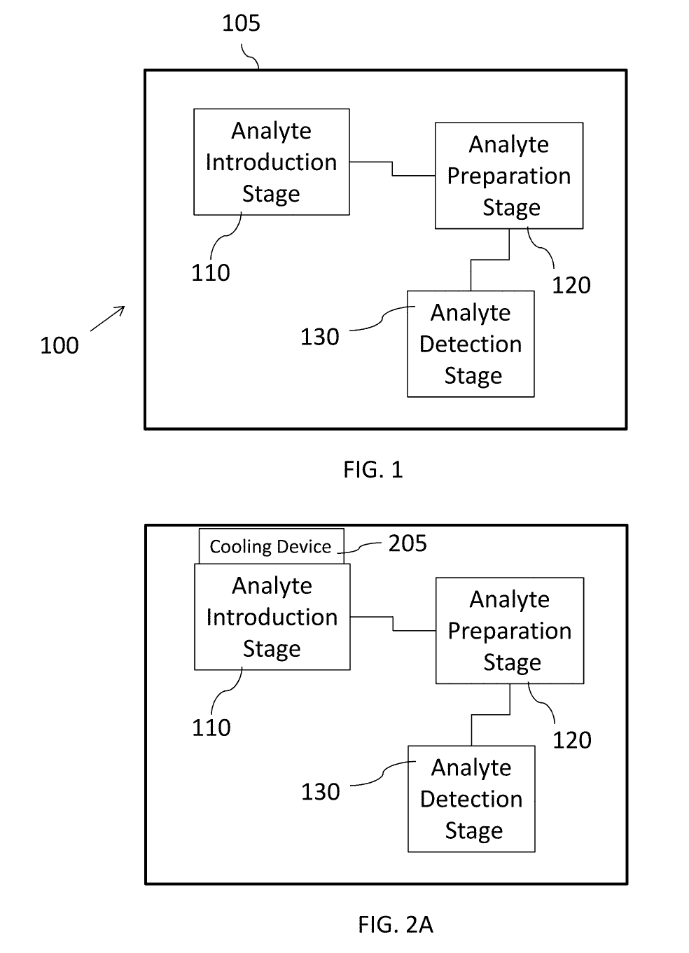

In certain examples, a general schematic of an instrument is shown in FIG. 1. The instrument 100 comprises an analyte introduction stage 110 coupled to an analyte preparation stage 120. The analyte preparation stage 120 is coupled to an analyte detection stage 130. Each of the stages 110, 120 and 130 may be contained within a housing 105 or any portion of any of the stages 110, 120 or 130 may be present outside of the housing 105 as desired. In some examples, the analyte introduction stage 110 is configured to permit an analyte to be introduced, injected or otherwise delivered to the instrument 100. For example, an injector, nebulizer, atomizer, sample platform or other suitable devices which can receive a solid, liquid or gaseous sample can be present in the introduction stage 110. The analyte preparation stage 120 typically performs one or more operations on the analyte. For example, the sample introduced into the analyte stage 120 from the stage 110 may comprise a mixture of materials, analytes, etc. which can be ionized, separated, chemically reacted with a substance or otherwise altered or acted upon in some manner prior to providing the resulting analytes to the detection stage 130. The detection stage 130 may be configured to detect individual analytes or collection of analytes using suitable methods including, but not limited to, optical methods, electronic methods, mass spectrometry methods, chemical methods and physical methods.

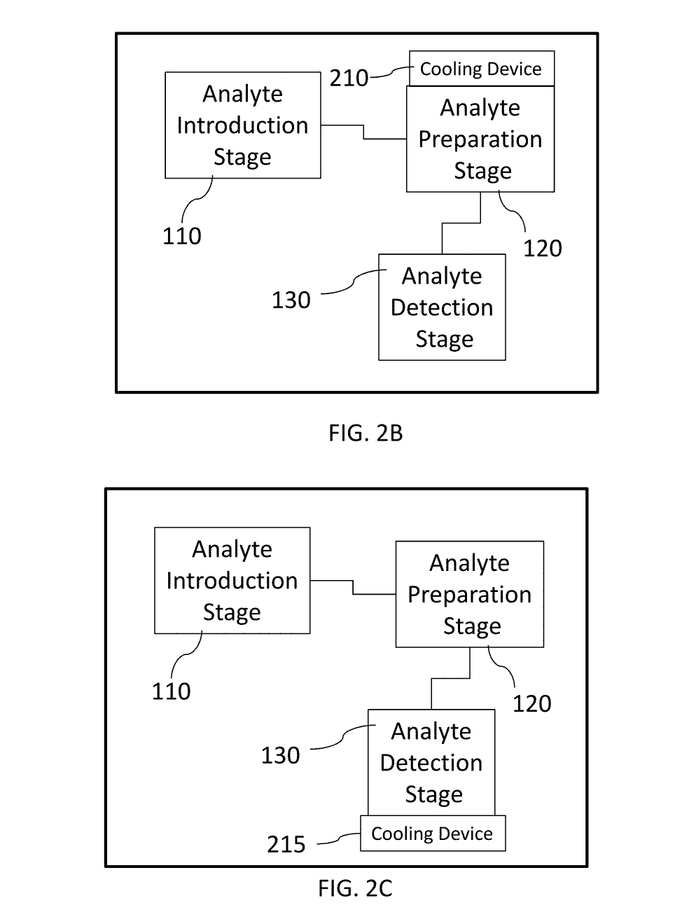

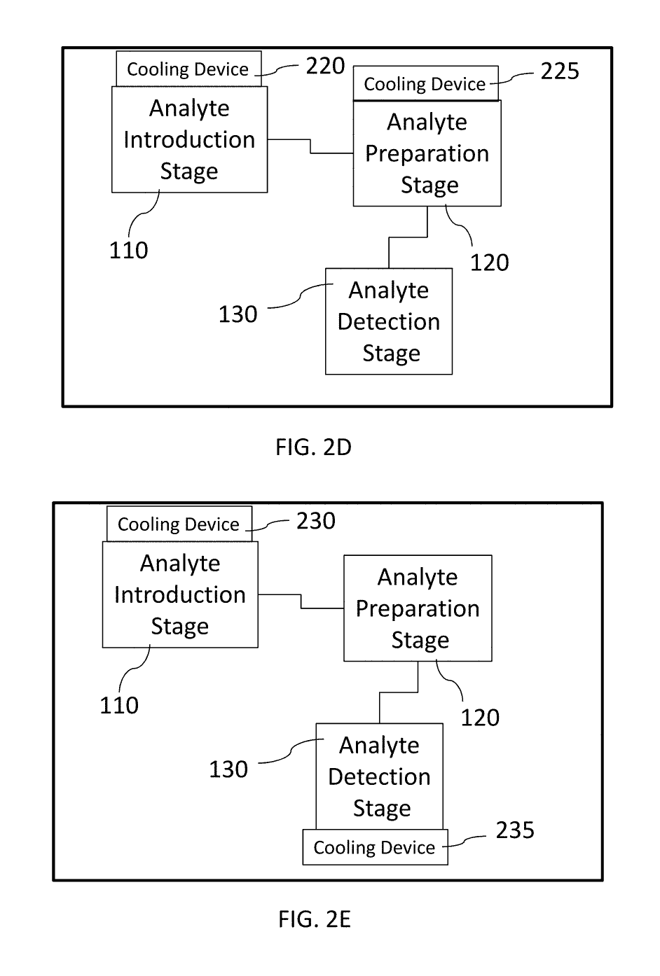

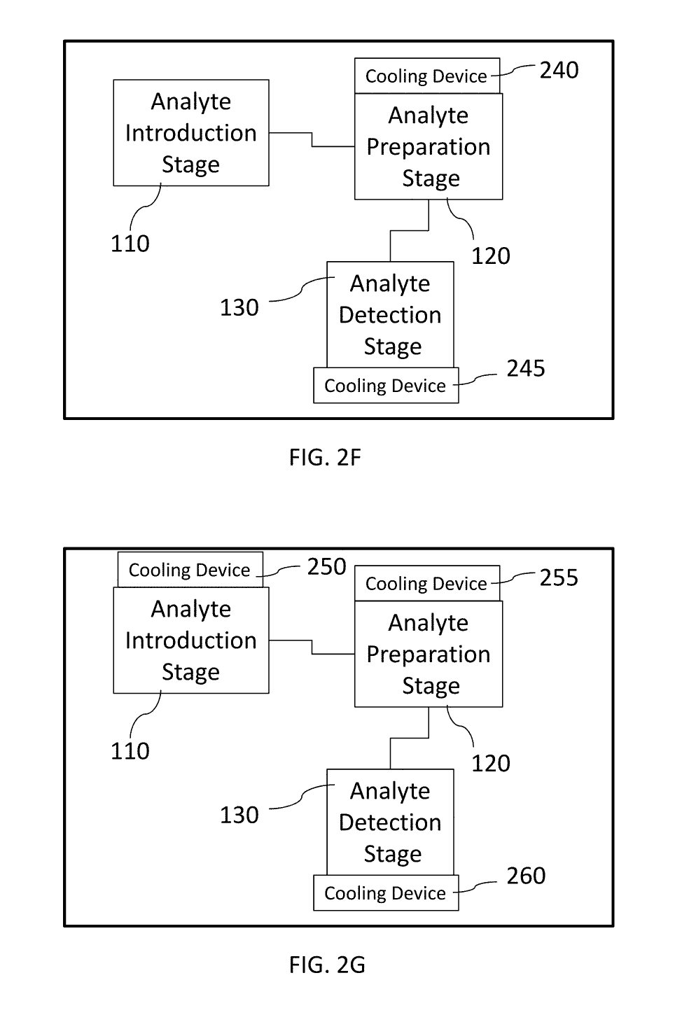

In some instances, one or more of the stages 110, 120, 130 may comprise a cooling device as described herein, e.g., a passive cooling device comprising a thermosyphon, thermally coupled to one or more components of that particular stage. Various illustrations are shown in FIGS. 2A-2G. In FIG. 2A, the sample introduction stage 110 comprises a passive cooling device 205 thermally coupled to one or more components. In FIG. 2B, the sample operation stage 120 comprises a passive cooling device 210 thermally coupled to one or more components. In FIG. 2C, the sample detection stage 130 comprises a passive cooling device 215 thermally coupled to one or more components. In FIG. 2D, both the sample introduction stage 110 and the sample operation stage 120 each comprise a passive cooling device 220, 225, respectively, thermally coupled to one or more components. In FIG. 2E, both the sample introduction stage 110 and the sample detection stage 130 each comprise a passive cooling device 230, 235, respectively, thermally coupled to one or more components. In FIG. 2F, both the sample operation stage 120 and the sample detection stage 130 each comprise a passive cooling device 240, 245, respectively, thermally coupled to one or more components. In FIG. 2G, all three stages 110, 120, 130 comprise a passive cooling device 250, 255 and 260, respectively, thermally coupled to one or more components.

In other instances, a single passive cooling device can be thermally coupled to more than one of the stages 110, 120 and 130 if desired. Where the instrument comprises more than one cooling device, the cooling devices may be the same or they may be different. In some configurations, the cooling devices present in any one or more of the stages 110, 120 and 130 may be thermally coupled to a non-processor component of the instrument stage. For example, microprocessors often include heat sinks thermally coupled to them to maintain the microprocessor below a desired temperature. While the cooling devices described herein can be used to cool a microprocessor present in one or more of the stages 110, 120, and 130, certain configurations use the cooling devices to cool non-microprocessor components including non-microprocessor transistors, pump motors, induction devices, interfaces between the instrument stages, injectors, nebulizers and other non-microprocessor components that can be present in one of the stages 110, 120 and 130. If desired, a passive cooling device as described herein can be used to cool a microprocessor and a non-microprocessor component in any one or more of the stages 110, 120 and 130.

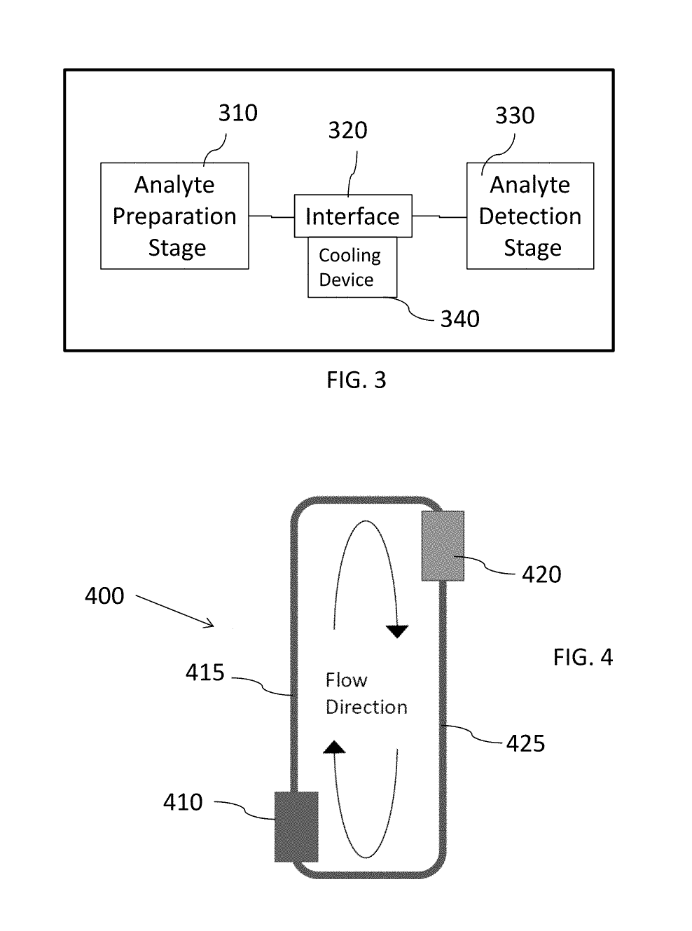

In certain examples, the cooling devices can be thermally coupled to an interface between various instrument stages. Referring to FIG. 3, an interface 320 is shown as being present between an analyte preparation stage 310 and an analyte detection stage 330. The interface 320 may comprise an associated cooling device 340 thermally coupled to one or more components of the interface 330. The interface 320 generally provides analyte from one the stage 310 of the instrument to the stage 330 of the instrument which may be operating at a different pressure or temperature. For example, the interface 320 may comprise sampler and skimmer cones positioned between an ionization source and a mass analyzer. The ionization source, e.g., an inductively coupled plasma, operates at roughly atmospheric pressure (1-2 Torr), whereas the mass analyzer operates under high vacuum (less than 10⁻⁵ Torr). The interface permits transfer of the center portion of the ion beam from the atmospheric source to the low pressure mass analyzer. The sampler cones, skimmer cones or both can be thermally coupled to the cooling device to control its temperature. In particular, positioning of the interface near a high temperature plasma requires cooling of the interface for proper operation and to prevent destruction of the interface. The passive cooling device can be thermally coupled to the interface to remove heat from the interface. In other instances, the interface may be present between the analyte introduction stage and an analyte preparation stage, e.g., the interface may comprise a nebulizer configured to introduce a sample into an ionization source such as an inductively coupled plasma.

In certain examples, the cooling devices used with the instrument components may comprise a loop thermosyphon, or be configured as a loop thermosyphon, to permit passive operation of the cooling device. Without wishing to be bound by any particular scientific theory, a loop thermosyphon uses passive heat exchange without the need to use a mechanical pump to force a fluid through the system. Convection results when heat is transferred from a component to the thermosyphon. This heat transfer provides a temperature difference from one side of a loop to the other. The fluid which receives the heat from the component to be cooled is less dense than the cooler fluid of the loop and will move or float above the cooler fluid. This exchange causes the cooler fluid to sink below the warmer fluid. Where the thermosyphon is constructed where the fluid loop is not entirely full of liquid, evaporation and condensation of the liquid can provide a thermosyphon heat pipe. The thermosyphon may comprise a condenser to place the heated vapor back into a liquid form and return the liquid to an interface which is thermally coupled to the component of the instrument to be cooled. In some instances, the thermosyphon can be constructed and arranged so the condenser is present on an upper portion of the loop, e.g., is at a high point of the loop relative to gravity, to permit the heat vapor to naturally rise and to permit the condensed liquid to naturally fall under gravitational forces. Heat is released as the vapor is condensed back into a liquid at the condenser. If desired, some portion of the cooling device, e.g., the condenser, can be positioned outside of the instrument housing to assist in cooling of the vapor and recondensing the vapor back to a liquid.

Referring to FIG. 4, a general illustration of a passive cooling device is shown. The cooling device 400 comprises an evaporator 410 fluidically coupled to a condenser 420 through a fluid line 415, e.g., an upcomer fluid line. The condenser 420 is fluidically coupled to the evaporator 410 through another fluid line 425, e.g., a downcomer fluid line. The cooling device 400 acts as a passive two phase heat transfer device. The driving force of the cooling device 400 is the head of liquid under the condenser 420. The liquid from the condenser 420 displaces the less dense vapor in the evaporator 410 driving the two phases to flow in the direction shown in FIG. 4. The overall mass flow rate is determined by the pressure balance. The passive cooling device 400 when configured in a loop form as shown in FIG. 4 has several attributes including unidirectional flow and the ability to transport heat over longer distances than a non-loop thermosyphon. Without wishing to be bound by any particular theory, the loop operating temperature is determined generally by the thermal resistance of the condenser and ambient conditions. Different types of fluids can be present within the loop as the working fluid to provide the fluid loop and different phase conditions. For example, water or a refrigerant can be present within the loop of the cooling device 400. While water provides good heat transfer and low saturation pressure, the use of water may result in freezing under certain operating conditions. Where freeze/thaw issues are a concern, the water can be replaced by a suitable refrigerant such as a propane based refrigerant, e.g., 1,1,1,3,3-Pentafluoropropane or R245fa. The exact refrigerant used may depend on the saturation pressure and overall operating conditions of the loop. For example, R134a refrigerant or other liquids which can undergo a phase change over the operating temperature of the cooling device 400 may also be used in certain instances depending on the components to be cooled.

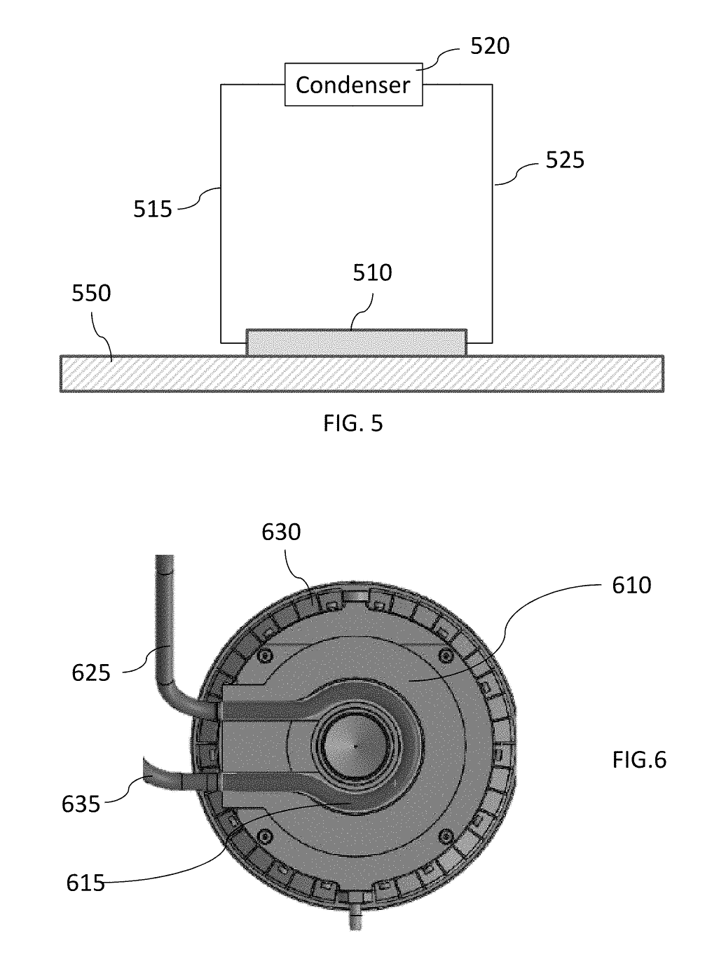

In some embodiments, the evaporator of the cooling device can be placed directly in contact with the component of the instrument to be cooled. For example and referring to FIG. 5, the evaporator may be configured as a plate 510 which is fluidically coupled to a condenser 520 through an upcomer fluid line 515 and is fluidically coupled to the condenser 520 through a downcomer fluid line 525. The plate 510 may sit directly against the component to be cooled to provide high surface area contact between the evaporator 510 and the component to be cooled. In this illustration, the plate evaporator 510 is thermally coupled to a backside of a printed circuit board 550, e.g., adjacent to power transistors which can be used to provide radio frequency signals to an induction device, to remove the heat from that particular area of the printed circuit board. The plate 510 may directly contact the printed circuit board 550 or one or more materials can be present between the plate 510 and the printed circuit board 550 to enhance heat transfer to the evaporator. In use of the loop thermosyphon, heat from the power transistors is transferred to the evaporator 510, which causes liquid in the loop to vaporize. This vapor rises through the upcomer fluid line 515 and is condensed by the condenser 520. The liquid is returned to the plate 510 through the downcomer fluid line 525. While not shown, one or more fans or separate cooling devices can be thermally coupled to the condenser 520 to assist in controlling of the condenser. The exact temperature of the condenser 520 may vary and desirably the condenser temperature is below the condensation temperature of the liquid in the loop, e.g., at least 20 deg. Celsius, at least 30 deg. Celsius, at least 40 deg. Celsius, or at least 50 deg. Celsius lower than the condensation temperature of the fluid in the loop thermosyphon. In some instances, the condenser can be at ambient room temperature, e.g., about 23-25 deg. Celsius, by positioning the condenser outside of the instrument. Ambient air flow can assist in keeping the condenser cool.

In configurations where the evaporator is configured as a plate, the evaporator loop portion of the plate may be integral to the plate or can be coupled to the plate in a suitable manner. For example, the plate may comprise an integral loop which fluidically couples to the downcomer and upcomer fluid lines to deliver liquid to the plate and/or carry vapor away from the plate. In other examples, the evaporator can be configured as a separate loop which can thermally couple to a plate or other device that contacts the component to be cooled. For example, the evaporator loop may sit on top of a plate which contacts the component to be cooled or the evaporator loop can contact the component to be cooled and a plate can be placed on top of the evaporator loop to retain the evaporator loop to the component. In other configurations, two plates can be present with the evaporator loop sandwiched between them. For example, where a circular component or circular area is to be cooled, then the evaporator may take the form of a circular loop or circular plate which can be placed directly in contact with the circular area to be cooled. One illustration is shown in FIG. 6. The cooling device comprises a grooved plate 610 thermally coupled to the evaporator loop 615 of a loop thermosyphon 600 By placing the plate 610 on the component 630 to be cooled, the surface area of the evaporator portion 615 of the loop thermosyphon is increased to provide increase heat transfer from the component 630 to be cooled to the evaporator loop 615. To ensure high heat transfer from the plate 610 to the loop 615, the piping or tubing of the loop 615 can be soldered to the plate 610, integral to the plate 615 or otherwise coupled to the plate 615 in a suitable manner to provide close to 100% contact area between the plate 610 and the underside of the loop 615 coupled to the plate 610. Heat transfer then efficiently occurs from the component 630 to the plate 610 and into the loop 615. Vapor in the loop 615 is provided to a condenser (not shown) through an upcomer fluid line 635. Condensed liquid is returned to the loop 615 through a downcomer fluid line 625. While not shown, the plate 610 may comprise a central opening or aperture to permit analyte to travel through the opening if the component 630 to be cooled is designed to pass certain analyte through the central opening.

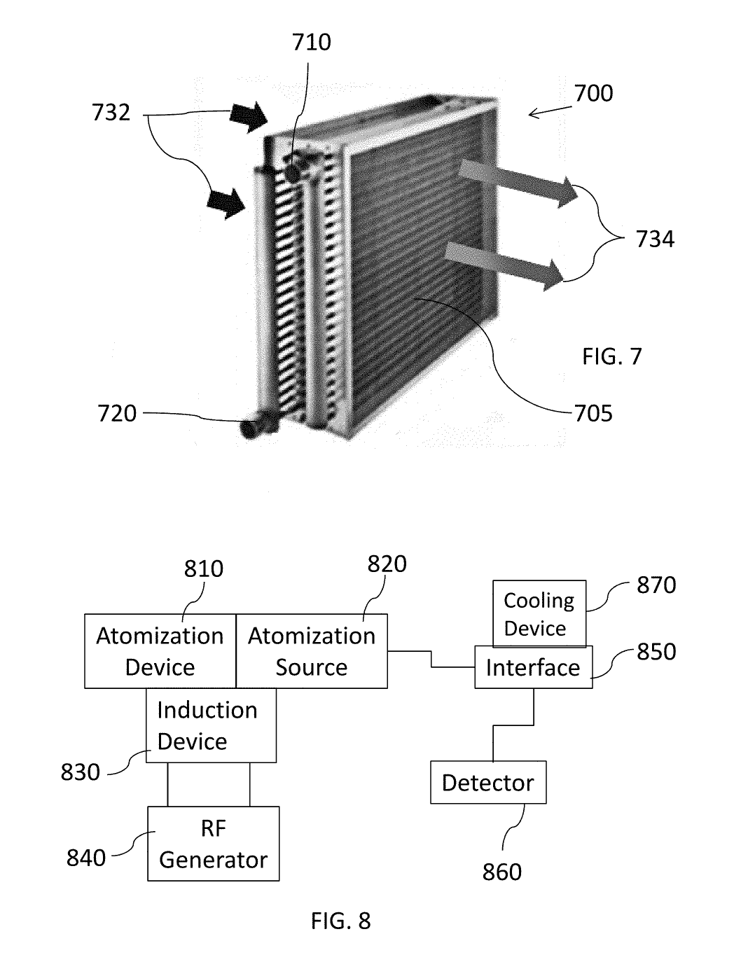

In certain configurations, the condenser of the loop thermosyphons described herein may comprise one or more fins or be configured similar to a radiator to enhance cooling of the vapor received from the evaporator. One configuration is shown in FIG. 7. The condenser 700 comprises an upcomer inlet 710 and a downcomer outlet 720. The inlet 710 can be fluidically coupled, e.g., by welding, soldering, brazing, etc., the upcomer fluid line (not shown) to the inlet 710. Similarly, the outlet 720 can be fluidically coupled, e.g., by welding, soldering, brazing, etc., the downcomer fluid line (not shown) to the outlet 720. The condenser 700 comprises a main body 705 comprising a plurality of fins to assist in dissipation of heat by the condenser 700. The heat may radiant on its own or air can be blown onto the condenser 700 in the directions of arrows 732 to assist in carrying away heat in the direction of arrows 734 from the condenser 700. In certain configurations, the body 705 of the condenser 700 may comprise metals such as aluminum, copper, or alloys such as nickel chromium alloys. In other instances, the body 705 of the condenser 700 may comprise one or more plastics which can be coated with a metal material if desired. The use of high temperature plastics, for example, can reduce the overall weight of the loop thermosyphon and can provide for easier coupling of the various components to each other.

In certain examples, the downcomer fluid line and/or the upcomer fluid lines may be produced from the same materials present in the body 705. In some instances, the upcomer fluid line may comprise a metal, and the downcomer fluid line may comprise a metal or other material such as a plastic. The exact shape and configuration of the upcomer and downcomer fluid lines is not critical. The upcomer fluid line desirably maintains the working fluid in a vapor phase to permit flow into the condenser. Heat from the instrument can transfer to the upcomer fluid line (at least to some extent) to keep the upcomer fluid line at a certain temperature The downcomer fluid line may be insulated to permit the liquid from the condenser to remain as a liquid until it reaches the evaporator component of the loop thermosyphon. The insulation may be, for example, metal coatings such as ceramics, glass coatings, fiber insulation, foam insulation or may take other forms. If desired, the loop thermosyphon may comprise two or more condensers to assist in converting the vapor of the working fluid back to a liquid. These condensers can be coupled in parallel, for example, to increase the overall capacity of the loop thermosyphon. In some examples, the condenser may be fluidically coupled to its own cooling device, e.g., a fan, Peltier cooler, etc. to assist in providing a temperature difference between the evaporator and the condenser. In addition, one or more valves or other components can be present in the condenser to restrict or promote fluid flow within the loop thermosyphon and/or to assist in pressure control.

In certain examples, the cooling devices described herein can be used to cool one or more electrical component of a radio frequency generator present in an instrument. For example, inductively coupled plasma instruments use a gas and induction devices to generate a plasma. The plasma can ionize and/or atomize analyte species, which are provided to a detector for detection. To provide the inductive fields used to sustain the plasma in a torch, one or more induction devices provide radio frequency energy into the torch. A radio frequency generator is electrically coupled to the induction device, which typically surrounds some portion of the torch. This generator comprises a pair (or pairs) of high power transistors which are used to power the induction devices. The transistors should be kept below a threshold temperature for proper operation, to reduce the likelihood of transistor breakdown and extend the overall life of the transistors. The presence of the hot plasma acts to increase the overall temperature near the power transistors. By thermally coupling one or more of the cooling devices described herein to the power transistors, the temperature of the power transistors can be better controlled.

Referring to FIG. 8, a block diagram of an instrument is shown. The instrument 800 comprises an atomization device 810, e.g., a torch configured to sustain an atomization source 820, e.g., a plasma or a flame. The atomization device 810 is typically positioned within some portion of an induction device 830 that provides radio frequency energy frequency energy into the received portion of the atomization device. A radio frequency generator 840 is electrically coupled to the induction device 830 to provide power to the induction device 830 and sustain the atomization source 820 in the atomization device 810. An interface 850 is present between the atomization device 810 and a detector 860. The interface 850 may comprise, for example, an aperture or opening which can receive analyte species from the atomization source 820 and provide those, e.g., permit passage of, the analyte species to the detector 860 from the interface 850. A cooling device 870 as described herein, e.g., a loop thermosyphon can be thermally coupled to the interface 850 to maintain the interface at a desired temperature. In other instances, the interface 850 may comprise an integral cooling device, e.g., the loop thermosyphon may form part of the interface 850.

In certain configurations, the instrument 800 does not include a chiller configured to cool the interface. For example, many existing plasma devices use a liquid cooled by a chiller to cool various components. The chiller adds complexity, cost and requires increased space. The cooling devices described herein can be used in place of the chiller to simplify overall instrument assembly and operation. In some examples, cooling device 870 is configured as a loop thermosyphon. For example, the loop thermosyphon can take any of the configurations described herein. In some instances, the loop thermosyphon comprises a plate evaporator, whereas in other configurations, the evaporator is coupled to the interface with at least one plate. In other examples, the loop thermosyphon comprises an evaporator fluidically coupled to a condenser through a downcomer fluid line and fluidically coupled to the condenser through an upcomer fluid line. In certain examples, the condenser is positioned external to a housing comprising the atomization device and the interface. For example, the condenser can be moved away from the hot atomization source 820 by placing the condenser outside of the instrument housing. In some configurations, the passive cooling device 870 is further thermally coupled to a transistor of the radio frequency generator 880 and is configured to simultaneously cool the interface 850 and the transistor of the radio frequency generator 880. In other configurations, a second passive cooling device separate from the cooling device 870 may be present in the instrument 800. For example, a second passive cooling device thermally coupled to a transistor of the radio frequency generator 880 while the cooling device 870 remains thermally coupled to the interface 850. In some examples, the second passive cooling device is configured as a second loop thermosyphon, which may be configured similar or different as the loop thermosyphon of the cooling device 870. For example, the second loop thermosyphon may comprise an evaporator fluidically coupled to a condenser through a downcomer fluid line and fluidically coupled to the condenser through an upcomer fluid line.

In certain instances, the cooling device 870 can be configured to provide heat to the interface to pre-heat the interface 850. For example, it may be desirable to heat the interface 850 to a certain temperature prior to initiating measurements using the instrument 800. In such cases, hot air can be blow over the condenser, for example, to provide heated liquid to the interface 850. Thermal transfer from the cooling device 870 to the interface 850 can pre-heat the interface. Once the instrument is operating, the hot air can be removed to permit the cooling device to operate in a normal loop thermosyphon manner to remove heat from the interface 850. In some instances as described in more detail herein, the passive cooling device 870 comprises a plate configured to sandwich the evaporator to the interface 850 to increase surface area contact between an evaporator loop of the cooling device 870 and the interface 850. For example, the passive cooling device 870 can be configured as a loop thermosyphon, in which the evaporator loop is sandwiched between the plate and a second plate comprising a groove to receive the evaporator loop, in which the second plate is coupled to the interface 850, and in which the evaporator loop, the plate and the second plate are coupled to each other through a solder joint. The presence of a solder joint may enhance heat transfer from the interface 850 to the evaporator loop of the cooling device 870.

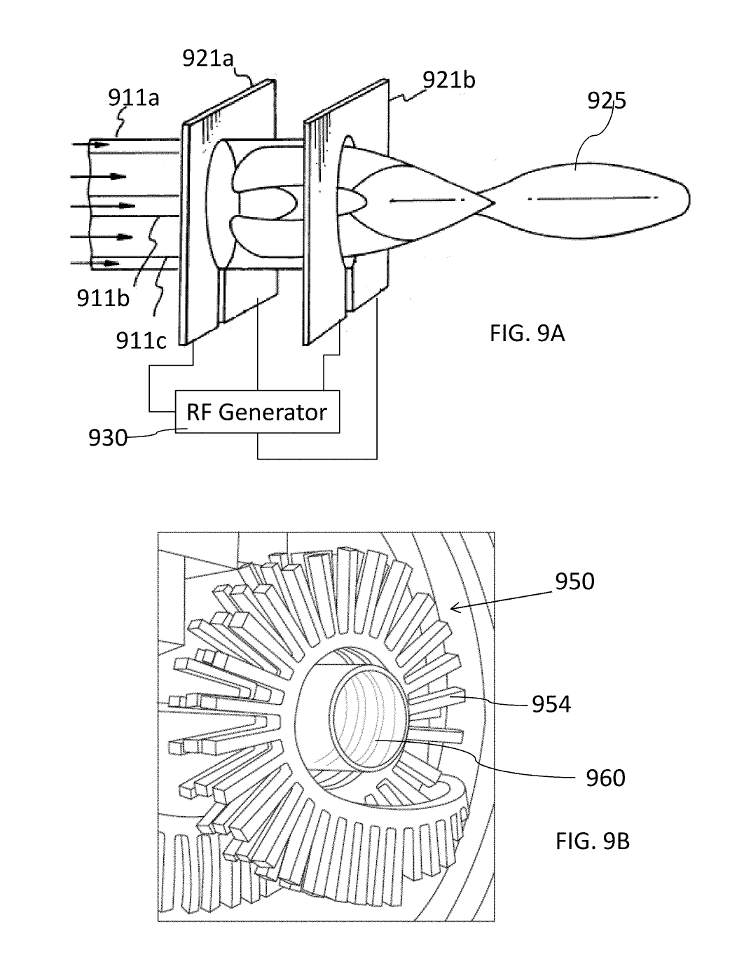

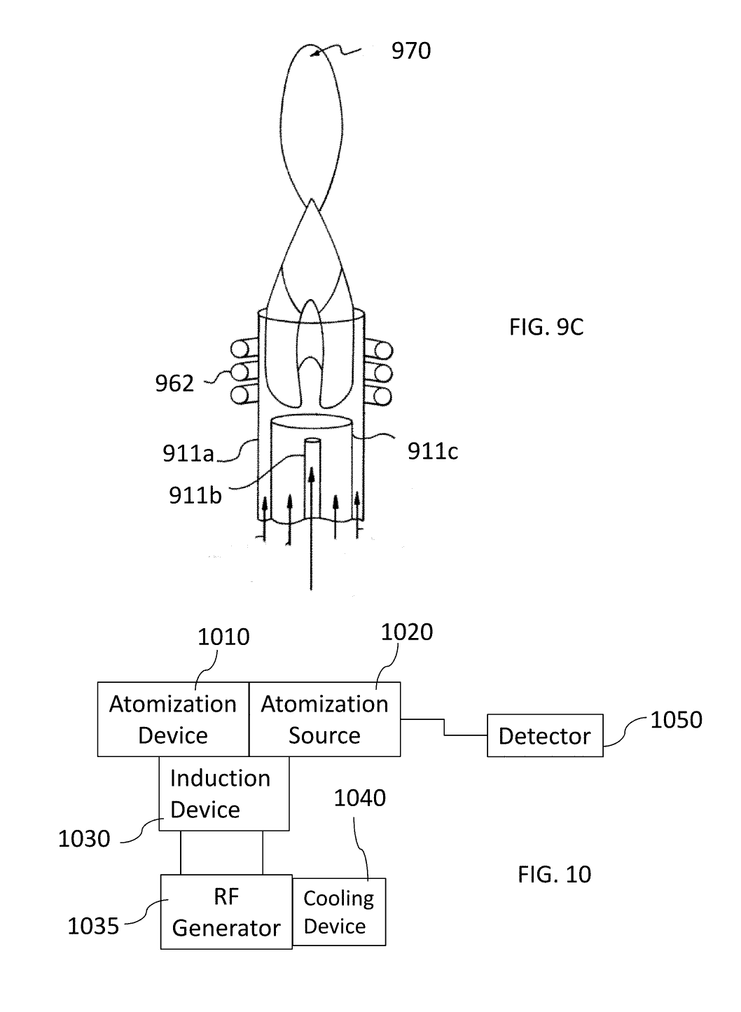

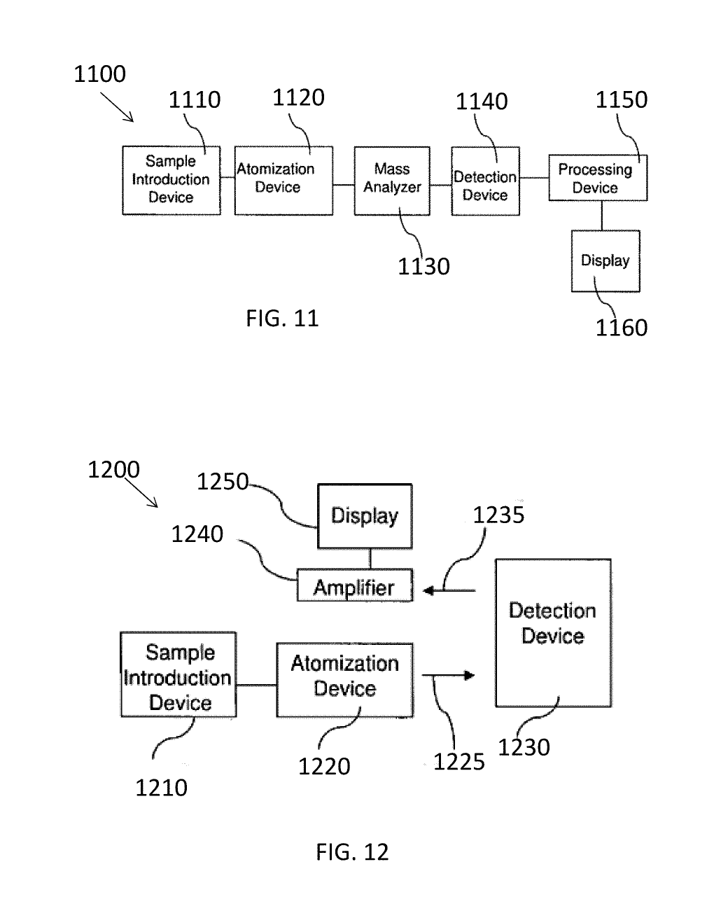

In certain examples, the atomization device, atomization source, and induction device of the instrument 800 may vary in configuration. In some instances, the atomization device takes the form of a torch as shown in FIG. 9A. The torch comprises three concentric tubes 911a, 911b and 911c, though the torch may take other forms as described for example in U.S. Patent Publication Nos. 20160255711, 20080173810, and 20110272386, the entire disclosure of each of which is incorporated herein by reference. The torch can be placed within some region of an induction device comprising plate electrodes 921a, 921b. An atomization source 925 such as, for example, an inductively coupled plasma can be sustained within the torch using inductive energy from the plates 921a, 921b. A radio frequency generator 930 is shown as electrically coupled to each of the plates 921a, 921b. While plate electrodes 921a, 921b are shown in FIG. 9A, induction devices including an induction coil 950 comprising at least one radial fin 952 (see 952 in FIG. 9B which surrounds a torch 960) or an conventional induction coil (see coil 962 in FIG. 9C which surrounds concentric tubes 911a, 911b and 911c and provides a plasma 970) or capacitive devices can be used in place of the induction devices to provide energy into the torch to sustain the atomization source 925. Illustrative induction coils are described, for example, in U.S. Pat. Nos. 9,433,073 and 9,360,403, the entire disclosure of which is hereby incorporated herein by reference for all purposes. In certain configurations, the detector 860 may take numerous forms including an optical detector, a mass spectrometer, electron capture detectors, electron multipliers, scintillation plates or other types of detectors. Illustrative detectors are described below in connection with FIGS. 11-13, for example.

In some configuration of the instrument 800, the atomization device 810 is configured to sustain an inductively coupled plasma, the induction device 830 comprises an induction coil comprising at least one radial fin, and the passive cooling device 870 comprises a loop thermosyphon comprising an evaporator fluidically coupled to a condenser through a downcomer fluid circuit and fluidically coupled to the condenser through an upcomer fluid circuit, and in which the evaporator of the loop thermosyphon is thermally coupled to the interface 850.

In some examples, where the instrument comprises an induction device, the induction device is typically electrically coupled to a radio frequency generator comprising a pair or pair of power transistors. A general illustration of such an instrument is shown in FIG. 10. The instrument comprises an atomization device 1010 configured to sustain an atomization source 1020, and an induction device 1030 configured to receive a portion of the atomization device 1010 to provide radio frequency energy into the received portion of the atomization device 1010. The instrument 1000 also comprises a radio frequency generator 1035 electrically coupled to the induction device 1030, in which the generator 1035 comprises a transistor pair (not shown) thermally coupled to a passive cooling device 1040. As noted herein, the generator 1035 may comprise a single transistor in some instances. The system 1000 also comprises a detector 1050 fluidically coupled to the atomization device 1010. Similar to instrument 900, the instrument 1000 may be configured without a chiller to cool the transistor or the transistor pair. In many existing instruments, the chiller provides a cooled liquid to a transistor or a transistor pair of the generator 1035 to cool them. This creates complexity and increases the likelihood of liquid leakage onto the generator 1035. In some examples, the passive cooling device 1040 is configured as a loop thermosyphon as described herein. For example, the loop thermosyphon comprises a closed loop heat pipe. In some examples, the cooling device 1040 is configured as a loop thermosyphon comprising an evaporator fluidically coupled to a condenser through a downcomer fluid line and fluidically coupled to the condenser through an upcomer fluid line. In certain examples, the condenser is positioned external to a housing comprising the atomization device 1010 and the radio frequency generator 1035. In some embodiments, the evaporator is coupled to the transistor or the transistor pair through at least one plate. For example, the evaporator may be integral to the plate which is thermally coupled to the transistor or the transistor pair, e.g., at a backside of a printed circuit board where the transistor or the transistor pair is present. In other configurations, the evaporator may couple to the plate, e.g., through a groove in the plate, and the plate itself can be thermally coupled to the transistor or the transistor pair. Heat is transferred from the transistor or the transistor pair to the plate and onto the evaporator. In other examples, the passive cooling device is further thermally coupled to an interface (not shown) of the instrument 1000. For example, the interface may be a device between the atomization device 1010 and a sample introduction device (not shown), e.g., a nebulizer, atomizer, etc., configured to provide sample to the atomization source 1020. The passive cooling device can be used to control the temperature of the sample introduction device. In other instances, the interface can be positioned between other components of the system, e.g., between the atomization device 1010 and the detector 1050.

In some examples, the instrument 1000 may comprise a second passive cooling device thermally coupled to at least one of the induction device 1030 and the detector 1050. For example, the second passive cooling device can be thermally coupled to an induction device as described in connection with the induction devices shown in FIGS. 9A-9C. In other configurations, the second cooling device can be thermally coupled to one or more components of the detector 1050. For example, where the detector 1050 is an optical detector, the second cooling device may maintain the temperature of a photomultiplier tube (PMT) to reduce background noise by thermally coupling the second cooling device to the PMT. In certain configurations, the second cooling device is configured as a second loop thermosyphon. The second loop thermosyphon may be similar or different than the loop thermosyphon of the cooling device 1040. In some instances, the second loop thermosyphon comprises an evaporator fluidically coupled to a condenser through a downcomer fluid line and fluidically coupled to the condenser through an upcomer fluid line. If desired, the cooling device 1040 can provide heat to the transistor or the transistor pair in a start-up phase to bring the components of the instrument 1000 up to a desired operating temperature prior to initiation of measurements.

In some configurations, the cooling device 1040 may comprise a plate configured to sandwich the evaporator to the transistor or the transistor pair (or a backside of a printed circuit board where the transistor or the transistor pair is mounted) to increase surface area contact between an evaporator loop of the cooling device 1040 and the transistor or the transistor pair. In other configurations, the passive cooling device 1040 can be configured as a loop thermosyphon, in which the evaporator loop is sandwiched between a first plate and a second plate comprising a groove to receive the evaporator loop, in which the second plate is thermally coupled to the transistor or the transistor pair (or a backside of a printed circuit board where the transistor or the transistor pair is mounted), and in which the evaporator loop, the plate and the second plate are coupled to each other through a solder joint. As noted herein, the presence of a solder joint can increase the efficiency of heat transfer from the plates to the evaporator loop of the cooling device 1040. The atomization device 1010 can be configured similar to any of the atomization devices discussed in connection with atomization device 1010, e.g., a flame, inductively coupled plasma, arc, spark, etc. The induction device 1030 can be configured similar to the induction devices discussed in connection with the induction device 1030, e.g., one or more plate electrodes, an induction coil, an induction coil comprising a radial fin, or the induction device can be replaced with a capacitive device if desired. The detector 1050 may be similar to the detector 1060, e.g., can include an optical detector, mass spectrometer or other types of detectors. In some configurations of the instrument 1000, the atomization device 1010 is configured to sustain an inductively coupled plasma, the induction device 1030 comprises an induction coil comprising at least one radial fin, and the passive cooling device 1040 comprises a loop thermosyphon comprising an evaporator fluidically coupled to a condenser through a downcomer fluid line and fluidically coupled to the condenser through an upcomer fluid line, in which the evaporator of the loop thermosyphon is thermally coupled to the transistor or the transistor pair of the radio frequency generator 1035. If desired, the loop thermosyphon may be integral to a printed circuit board comprising the transistor or the transistor pair to facilitate easier assembly of the instrument 1000. For example, the evaporator loop of the loop thermosyphon may be soldered to or otherwise coupled to the printed circuit board at a site where the transistor of the transistor pair is intended to be present to provide heat removal from the transistor or the transistor pair.

In certain examples, the passive cooling devices described herein can be used in non-instrument systems if desired. For example, the system can be configured to sustain an inductively coupled plasma and comprise an interface fluidically coupled to a torch configured to sustain a plasma in a section of the torch using an induction device, in which the interface is thermally coupled to a passive cooling device comprising a loop thermosyphon configured to cool the interface. The system can be used, for example, as a chemical reactor, to deposit materials onto a surface or substrate, in welding or cutting operations or in other instances where a plasma can be used. In some examples, the loop thermosyphon is configured as a closed loop heat pipe. For example, the loop thermosyphon comprises an evaporator configured to thermally couple to the interface, and may comprise a condenser fluidically coupled to the evaporator through a downcomer fluid line and through an upcomer fluid line. In some examples, the induction device of the system may comprise one of an induction coil comprising a radial fin, an induction coil and a plate electrode as described in connection with FIGS. 9A-9C. The system may also comprise a radio frequency generator comprising a transistor or a transistor pair, in which the radio frequency generator is electrically coupled to the induction device to sustain the plasma within the section of the torch. If desired, a second passive cooling device thermally coupled to the transistor or the transistor pair of the radio frequency generator. In some examples, the second passive cooling device is also configured as a loop thermosyphon which may be the same or may be different than the loop thermosyphon of the first cooling device, e.g., the evaporator, condenser, etc. may have a different size or different materials can be present. In some examples, the loop thermosyphon of the second passive cooling device comprises an evaporator fluidically coupled to a condenser through a downcomer fluid line and fluidically coupled to the condenser through an upcomer fluid line. In certain instances, the system may be used without the use of, or the presence of, a chiller configured to cool the interface.

In other configurations, a system may comprise a torch configured to sustain the plasma, an induction device configured to receive a portion of the torch to provide radio frequency energy to the received portion of the torch, and a radio frequency generator electrically coupled to the induction device, in which at least one transistor or transistor pair of the radio frequency generator is thermally coupled to a passive cooling device configured to cool the transistor or the transistor pair. In some configurations, the passive cooling device is configured as a loop thermosyphon as described herein. In certain examples, the loop thermosyphon comprises a closed loop heat pipe. For examples, the loop thermosyphon comprises an evaporator fluidically coupled to a condenser through a downcomer fluid line and fluidically coupled to the condenser through an upcomer fluid line. In some examples, the condenser is positioned at a higher height than the evaporator. In other examples, the induction device comprises one of an induction coil comprising a radial fin, an induction coil and a plate electrode. In some embodiments, the system comprises a second passive cooling device configured to thermally couple to the induction device or the torch. In some examples, the second passive cooling device is also configured as a loop thermosyphon which may be the same or may be different than the loop thermosyphon of the first cooling device, e.g., the evaporator, condenser, etc. may have a different size or different materials can be present. The second loop thermosyphon may comprise an evaporator fluidically coupled to a condenser through a downcomer fluid line and fluidically coupled to the condenser through an upcomer fluid line. In some configurations, the system does not include a chiller configured to cool the transistor or the transistor pair.

In certain embodiments, the cooling devices described herein can be used in a system configured to perform mass spectrometry (MS). For example and referring to FIG. 11, MS device 1100 includes a sample introduction device 1110, an atomization device 1120 which can comprise one or more of the torches described herein that can be used to sustain an atomization source, a mass analyzer 1130, a detection device 1140, a processing device 1150 and a display 1160. The sample introduction device 1110, the atomization device 1120, the mass analyzer 1130 and the detection device 1140 may be operated at reduced pressures using one or more vacuum pumps. In certain examples, however, only the mass analyzer 1130 and the detection device 1140 may be operated at reduced pressures. A cooling device as described herein, e.g., a loop thermosiphon, can be thermally coupled to any one or more of the components in FIG. 11. In a typical configuration, the cooling device may be thermally coupled to a pump of the mass analyzer 1130, a radio frequency generator of the atomization device 1120 or an interface (not shown) between the atomization device 1120 and the mass analyzer 1130. The sample introduction device 1110 may include an inlet system configured to provide sample to the atomization device 1120. The inlet system may include one or more batch inlets, direct probe inlets and/or chromatographic inlets. The sample introduction device 1110 may be an injector, a nebulizer or other suitable devices that may deliver solid, liquid or gaseous samples to the atomization device 1120. The atomization device 1120 may comprise any one of or more of the induction devices described herein. The mass analyzer 1130 may take numerous forms depending generally on the sample nature, desired resolution, etc. and exemplary mass analyzers may comprise one or more rod assemblies such as, for example, a quadrupole or other rod assembly. In some instances, the mass analyzer 1130 may comprise its own radio frequency generator. For example, a transistor of a radio frequency generator electrically coupled to rods of the mass analyzer may be thermally coupled to a cooling device to cool the transistor or transistor pair. The detection device 1140 may be any suitable detection device that may be used with existing mass spectrometers, e.g., electron multipliers, Faraday cups, coated photographic plates, scintillation detectors, etc., and other suitable devices that will be selected by the person of ordinary skill in the art, given the benefit of this disclosure. The processing device 1150 typically includes a microprocessor and/or computer and suitable software for analysis of samples introduced into MS device 1100. One or more databases may be accessed by the processing device 1150 for determination of the chemical identity of species introduced into MS device 1100. Other suitable additional devices known in the art may also be used with the MS device 1100 including, but not limited to, autosamplers, such as AS-90plus and AS-93plus autosamplers commercially available from PerkinElmer Health Sciences, Inc.

In certain embodiments, the torches described herein can be used in optical emission spectroscopy (OES). Referring to FIG. 12, OES device 1200 includes a sample introduction device 1210, an atomization device 1220 comprising one or more induction devices, torches, etc., and a detection device 1230. The sample introduction device 1210 may vary depending on the nature of the sample. In certain examples, the sample introduction device 1210 may be a nebulizer that is configured to aerosolize liquid sample for introduction into the atomization device 1220. In other examples, the sample introduction device 1210 may be an injector configured to receive sample that may be directly injected or introduced into the atomization device 1220. Other suitable devices and methods for introducing samples will be readily selected by the person of ordinary skill in the art, given the benefit of this disclosure. The detection device 1230 may take numerous forms and may be any suitable device that may detect optical emissions, such as optical emission 1225. For example, the detection device 1230 may include suitable optics, such as lenses, mirrors, prisms, windows, band-pass filters, etc. The detection device 1230 may also include gratings, such as echelle gratings, to provide a multi-channel OES device. Gratings such as echelle gratings may allow for simultaneous detection of multiple emission wavelengths. The gratings may be positioned within a monochromator or other suitable device for selection of one or more particular wavelengths to monitor. In certain examples, the detection device 1230 may include a charge coupled device (CCD). In other examples, the OES device may be configured to implement Fourier transforms to provide simultaneous detection of multiple emission wavelengths. The detection device may be configured to monitor emission wavelengths over a large wavelength range including, but not limited to, ultraviolet, visible, near and far infrared, etc. The OES device 1200 may further include suitable electronics such as a microprocessor and/or computer and suitable circuitry to provide a desired signal and/or for data acquisition. Suitable additional devices and circuitry are known in the art and may be found, for example, on commercially available OES devices such as Optima 2100DV series and Optima 5000 DV series OES devices commercially available from PerkinElmer Health Sciences, Inc. The optional amplifier 1240 may be operative to increase a signal 1235, e.g., amplify the signal from detected photons, and provides the signal to display 1250, which may be a readout, computer, etc. In examples where the signal 1235 is sufficiently large for display or detection, the amplifier 840 may be omitted. In certain examples, the amplifier 1240 is a photomultiplier tube configured to receive signals from the detection device 1230. Other suitable devices for amplifying signals, however, will be selected by the person of ordinary skill in the art, given the benefit of this disclosure. It will also be within the ability of the person of ordinary skill in the art, given the benefit of this disclosure, to retrofit existing OES devices with the atomization devices disclosed here and to design new OES devices using the atomization devices disclosed here. The OES devices may further include autosamplers, such as AS90 and AS93 autosamplers commercially available from PerkinElmer Health Sciences, Inc. or similar devices available from other suppliers. A cooling device as described herein may be thermally coupled to any one or more of the components of the system 1200. For example, a loop thermosiphon can be thermally coupled to a photomultiplier tube (PMT) of the detection device 1230 to reduce background noise and/or control the temperature of the PMT. Where the atomization device 1220 is configured as an inductively coupled plasma, a cooling device as described herein can be thermally coupled to a transistor or a transistor pair of a radio frequency generator electrically coupled to an induction device.

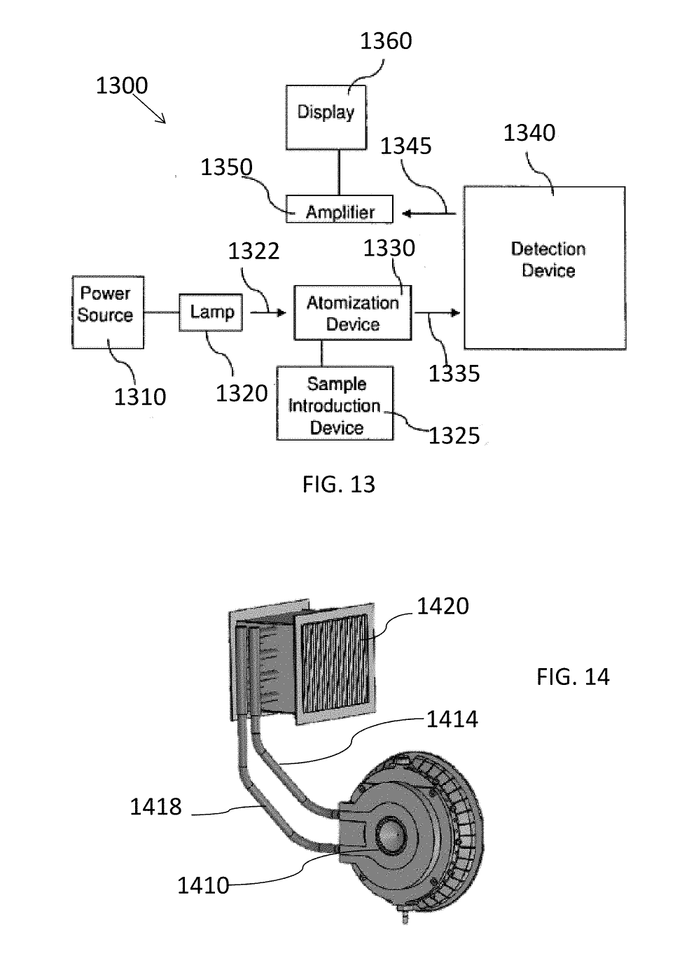

In certain examples, the torches described herein can be used in an atomic absorption spectrometer (AAS). Referring to FIG. 13, a single beam AAS 1300 comprises a power source 1310, a lamp 1320, a sample introduction device 1325, an atomization device 1330 comprising an induction device, torch, etc., a detection device 1340, an optional amplifier 1350 and a display 1360. The power source 1310 may be configured to supply power to the lamp 1320, which provides one or more wavelengths of light 1322 for absorption by atoms and ions. Suitable lamps include, but are not limited to mercury lamps, cathode ray lamps, lasers, etc. The lamp may be pulsed using suitable choppers or pulsed power supplies, or in examples where a laser is implemented, the laser may be pulsed with a selected frequency, e.g. 5, 10, or 20 times/second. The exact configuration of the lamp 1320 may vary. For example, the lamp 1320 may provide light axially along the torch body of the atomization device 1330 or may provide light radially along the atomization device 1330. The example shown in FIG. 13 is configured for axial supply of light from the lamp 1320. There can be signal-to-noise advantages using axial viewing of signals. The atomization device 1330 may be any of the atomization devices discussed herein, e.g., one comprising a torch, induction device, etc. or other suitable atomization devices that will be readily selected or designed by the person of ordinary skill in the art, given the benefit of this disclosure. As sample is atomized and/or ionized in the atomization device 1330, the incident light 1322 from the lamp 1320 may excite atoms. That is, some percentage of the light 1322 that is supplied by the lamp 1320 may be absorbed by the atoms and ions in the torch of atomization device 1330. The remaining percentage of the light 1335 may be transmitted to the detection device 1340. The detection device 1340 may provide one or more suitable wavelengths using, for example, prisms, lenses, gratings and other suitable devices such as those discussed above in reference to the OES devices, for example. The signal may be provided to the optional amplifier 1350 for increasing the signal provided to the display 1360. To account for the amount of absorption by sample in the atomization device 1330, a blank, such as water, may be introduced prior to sample introduction to provide a 100% transmittance reference value. The amount of light transmitted once sample is introduced into atomization chamber may be measured, and the amount of light transmitted with sample may be divided by the reference value to obtain the transmittance. The negative log₁₀ of the transmittance is equal to the absorbance. AS device 900 may further include suitable electronics such as a microprocessor and/or computer and suitable circuitry to provide a desired signal and/or for data acquisition. Suitable additional devices and circuitry may be found, for example, on commercially available AS devices such as AAnalyst series spectrometers commercially available from PerkinElmer Health Sciences, Inc. It will also be within the ability of the person of ordinary skill in the art, given the benefit of this disclosure, to retrofit existing AS devices with the atomization devices disclosed here and to design new AS devices using the atomization devices disclosed here. The AS devices may further include autosamplers known in the art, such as AS-90A, AS-90plus and AS-93plus autosamplers commercially available from PerkinElmer Health Sciences, Inc. A cooling device as described herein may be thermally coupled to any one or more of the components of the system 1300. For example, a loop thermosiphon can be thermally coupled to a photomultiplier tube (PMT) of the detection device 1340 to reduce background noise and/or control the temperature of the PMT. Where the atomization device 1320 is configured as an inductively coupled plasma, a cooling device as described herein can be thermally coupled to a transistor or a transistor pair of a radio frequency generator electrically coupled to an induction device. In certain embodiments, a double beam AAS device, instead of a single beam AAS device, comprising one of the cooling devices described herein may be used to measure atomic absorption of species.

In other instances, the loop thermosyphons described herein can be used to remove heat from an interface, a transistor, a transistor pair or other components. Further, additional loop thermosyphons can be present as desired to cool other components of the instruments and systems. A single loop thermosyphon can simultaneously cool two or more separate components if desired. The presence of a loop thermosiphon may also permit operation of plasma devices without the use of a shear gas to terminate the plasma at the end of a torch. This configuration may be particularly desirable as it simplifies the assemblies used to sustain plasmas. The loop thermosyphons can be thermally coupled to one or more fans, active cooling devices (e.g., refrigerant cooling devices comprising a compressor) or other devices which can assist in the loop thermosyphon cooling one or more components. As noted herein, the condenser of the loop thermosyphon can be positioned higher than the evaporator (relative to a surface which the system resides on) to facilitate natural flow through the loop thermosyphon. A portion of the condenser or all of the condenser may also be positioned outside of the housing of the system to increase flow through the loop thermosyphon.

The loop thermosyphons described herein can be present in a kit which permits an end user to thermally couple the loop thermosyphon to a desired component. Instructions may also be present in the kit to provide guidance to use the loop thermosyphon with a particular component to be cooled. In some instances, the kit comprises a loop thermosyphon constructed and arranged to thermally couple to an interface of an instrument (or other system) to cool the interface during operation of the instrument (or other system). In certain instances, the kit may also comprise a first plate configured to couple to the loop thermosyphon and the interface. In some embodiments, the kit may comprise a second plate configured to couple to the loop thermosyphon and the second plate to sandwich an evaporator loop of the loop thermosyphon between the first and second plates. In other configurations, the kit may comprise a loop thermosyphon integral to an interface of an instrument (or other system), in which the loop thermosyphon is configured to cool the interface during operation of the instrument (or other system). For example, an existing interface in an instrument or system can be removed and replaced with the interface comprising the integral loop thermosyphon. The passive nature of the loop thermosyphon permits its use without the need to electrically couple it to any power source. In additional configurations, a kit comprises a loop thermosyphon constructed and arranged to thermally couple to a transistor or a transistor pair of a radio frequency generator of an instrument to cool the transistor or the transistor pair during operation of the instrument. The kit may comprise instructions to mount the loop thermosyphon to the backside of a printed circuit board where the transistors reside.

Certain specific examples of cooling devices are described in more detail below.

### Example 1

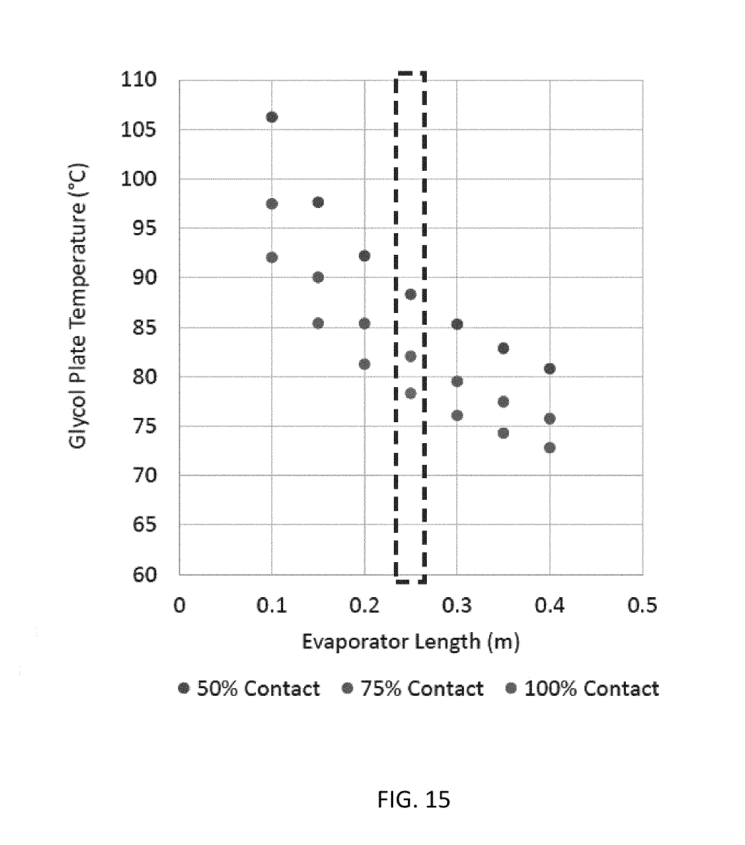

Loop thermosyphon cooling devices of various loop lengths were tested for their ability to transfer heat. The basic setup of the device is shown in FIG. 14 with the device including an evaporator loop 1410 and a condenser 1420. An upcomer fluid line 1414 and a downcomer fluid line 1418 are present. The tubing used was 0.375 inch outer diameter tubing. R245fa was used as the working fluid in the fluid in the loop. Ambient temperature was about 30 deg. Celsius. Air was provided to the condenser 1420 at a rate of about 75 CFM. The length of the evaporator loop 1410 and the percent contact area varied. The test results are shown in FIG. 15. Increasing the surface area contact of the evaporator loop 1410 decreased the evaporator loop 1410 thermal resistance and reduced the plate temperature. An evaporator length of about 0.24 meters to about 0.27 meters provides good thermal properties while keeping the overall length of the evaporator to a minimum.

### Example 2

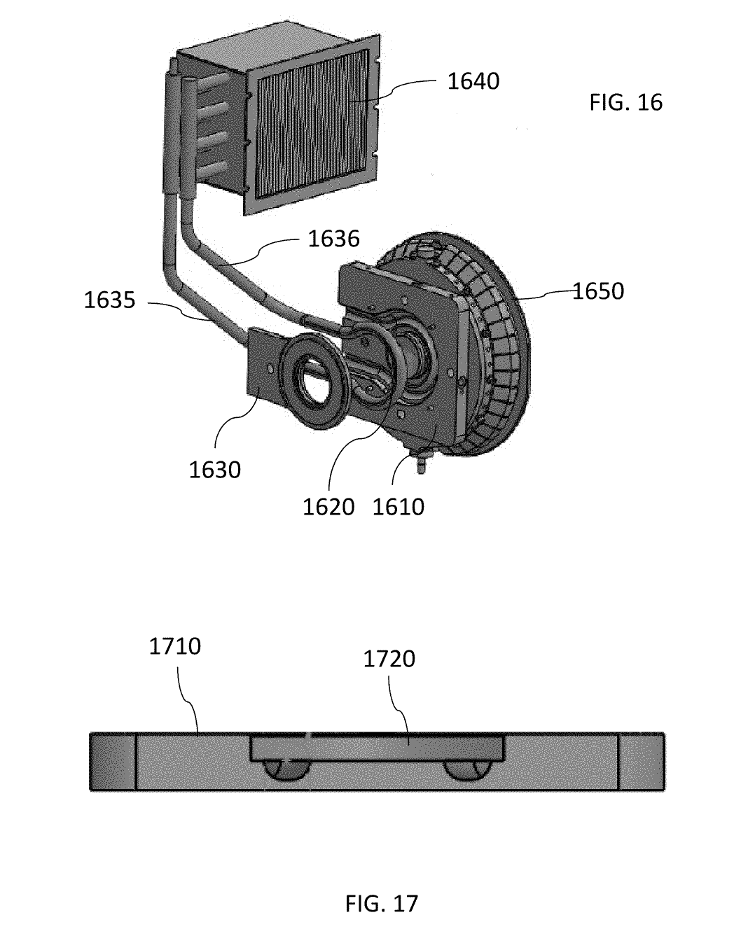

A cooling device can be produced by coupling a loop thermosyphon to an evaporator plate. Referring to FIG. 16, a bottom plate 1610 is shown that can be used to sandwich the evaporator loop 1620 between the bottom plate 1610 and a top plate 1630. The evaporator loop 1620 and condenser 1640 are connected by two fluid lines 1635, 1636 to provide the thermosyphon cycle. The evaporator loop plates 1610, 1630 form a clamshell around the evaporator loop 1620. Solder paste can be used to ensure good contact between the entire surface of the evaporator loop 1620 and the plates 1610, 1630. For example, solder paste can be placed into the grooves of the plates 1610, 1630 and around the evaporator loop 1610. Once the assembly is sandwiched together, the plates 1610, 1630 can be clamped and the assembly can be heated to provide the solder joint.

### Example 3

A side view of a plate which can be coupled to an evaporator loop is shown in FIG. 17. The plate 1710 may comprise a groove 1720 which can mimic the geometry of the evaporator loop. The center of the groove 1720 can be offset from the surface of the plate for an interference fit to provide good contact between the evaporator and the plate 1710 when they are clamped together.

### Example 4

An air cooled condenser can be used in the cooling devices. The condenser can be sized and arranged to provide a heat dissipation of about 1 kW at 30 deg. Celsius using 75-100 CFM of air blown onto the fins of the condenser. In some instances, the condenser can be about 4-6 inches in finned length, by about 3-5 inches in finned height by about 3-5 inches case depth. The exact number of fins per inch on the condenser may vary from about 10 fins to about 30 fins, for example.

The condenser can be sized to work with an evaporator loop temperature of about 60 deg. Celsius. to about 80 deg. Celsius. In one configuration, the evaporator loop may comprise ⅜″ outer diameter flattened copper tubing with a loop length of about 10-11 inches. The upcomer fluid line may comprise the same ⅜″ outer diameter copper tubing with a length of about 7-8 inches long, and the downcomer fluid line may comprise the same ⅜″ outer diameter tubing with a length of about 9-10 inches long.

### Example 5

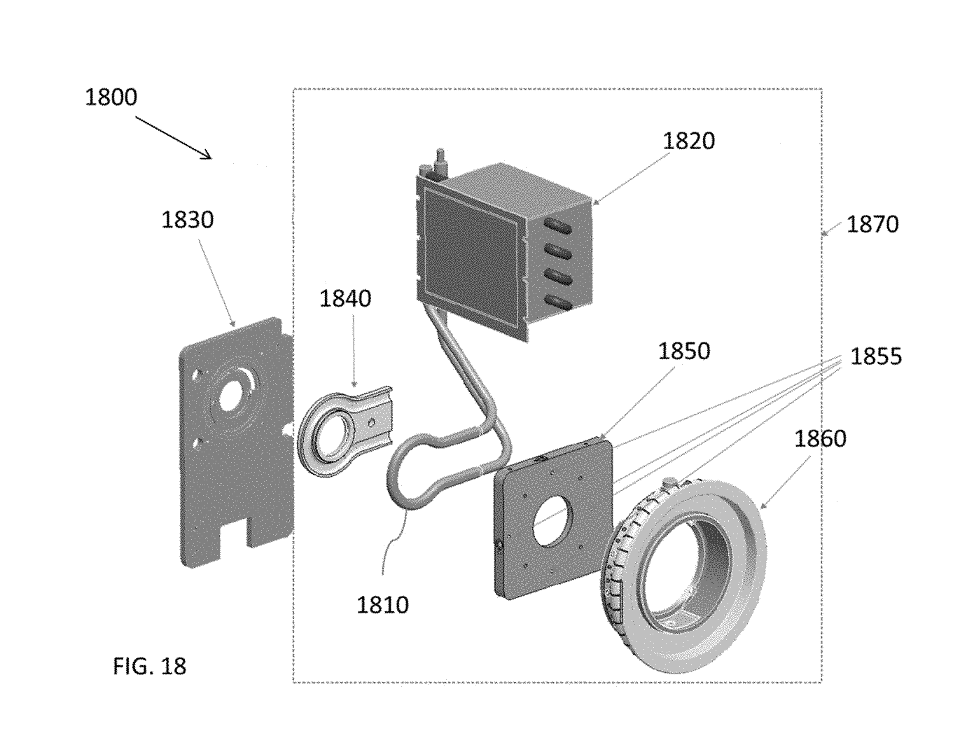

An exploded view of an interface comprising a loop thermosiphon is shown in FIG. 18. The interface 1800 comprises a loop thermosyphon comprising an evaporator loop 1810 fluidically coupled to a condenser 1820. A front plate 1830, a rear channel 1840, a front channel 1850 and an EMI interface 1860 are present. The front plate 1830 and the front channel 1850 sandwich the evaporator loop 1810. The front channel 1850 is held to the EMI interface 1860 using screws 1855. When the assembly 1800 is removed, all the components shown in the dashed line 1870 can be removed together.

### Example 6

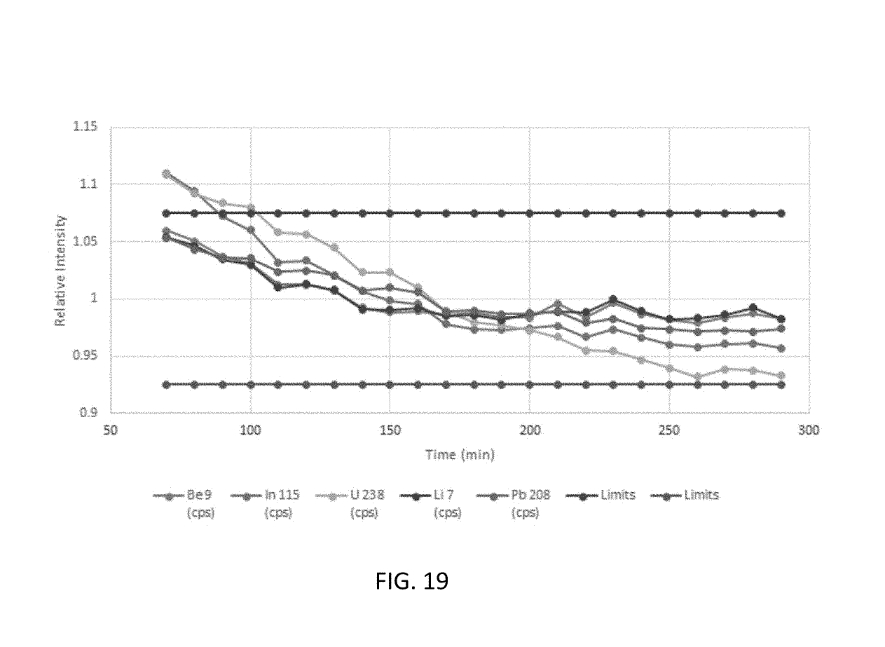

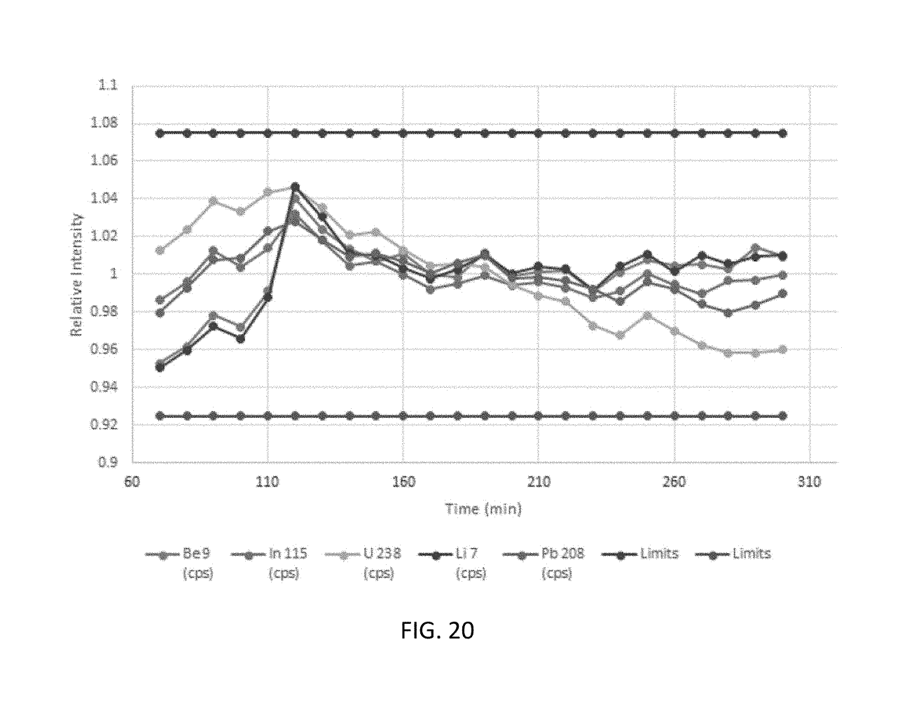

Two 100 Watt cartridge heaters were added to the interface. One cartridge heater was placed at a top right corner of the interface, and the other cartridge heater was placed at a bottom left corner of the interface. Various values were measured to determine the signal stability in the absence of heating using the cartridge heaters (FIG. 19) and in the presence of heating using the cartridge heaters (FIG. 20).

As shown in FIG. 19, signal drift over time is observed when the interface is not heated. Heating of the interface stabilized the signals and provides a more flat response over time as compared to not using heating as shown in FIG. 20. The stabilized interface temperature in the absence of heating was about 107-112 degrees Celsius. The interface temperature in the presence of heating was about 118-120 degrees Celsius. Heating of the interface provided a lower degree of temperature fluctuation than was observed without any heating.

When introducing elements of the examples disclosed herein, the articles “a,” “an,” “the” and “said” are intended to mean that there are one or more of the elements. The terms “comprising,” “including” and “having” are intended to be open-ended and mean that there may be additional elements other than the listed elements. It will be recognized by the person of ordinary skill in the art, given the benefit of this disclosure, that various components of the examples can be interchanged or substituted with various components in other examples.

Although certain aspects, examples and embodiments have been described above, it will be recognized by the person of ordinary skill in the art, given the benefit of this disclosure, that additions, substitutions, modifications, and alterations of the disclosed illustrative aspects, examples and embodiments are possible.

1. An instrument comprising:
an analyte introduction stage;
an analyte preparation stage fluidically coupled to the analyte introduction stage and configured to receive analyte from the analyte introduction stage; and
an analyte detection stage fluidically coupled to the analyte preparation stage and configured to receive analyte from the analyte preparation stage, in which at least one of the analyte introduction stage, the analyte preparation stage and the analyte detection stage comprises a loop thermosyphon thermally coupled to a component in one of the analyte introduction stage, the analyte preparation stage and the analyte detection stage.

2. The instrument of claim 1, in which the analyte introduction stage comprises one of a nebulizer, an injector and an atomizer.

3. The instrument of claim 1, in which the analyte preparation stage comprises one of a plasma, a flame, an arc, and a spark.

4. The instrument of claim 1, in which the analyte preparation stage comprises a torch, an induction device and a radio frequency generator electrically coupled to the induction device, in which the torch is configured to receive a section of the induction device and provide radio frequency energy into the section of the torch to sustain a plasma in the section of the torch, in which the loop thermosyphon is thermally coupled to a transistor of the radio frequency generator.

5. The instrument of claim 1, in which the analyte detection stage comprises a mass analyzer fluidically coupled to a detector.

6. The instrument of claim 5, further comprising an interface between the analyte preparation stage and the mass analyzer, in which the interface is thermally coupled to the loop thermosyphon.

7. The instrument of claim 5, further comprising an interface between the analyte preparation stage and the mass analyzer, in which the loop thermosyphon is integral to the interface.

8. The instrument of claim 5, in which the loop thermosyphon thermally couples to the interface through a first plate and a second plate.

9. The instrument of claim 8, in which the second plate comprises a groove to receive an evaporator loop of the loop thermosyphon and the first plate couples to the second plate to sandwich the evaporator loop between the first plate and the second plate, wherein the second plate couples to the interface.

10. The instrument of claim 1, further comprising a second loop thermosyphon thermally coupled to at least one of the analyte introduction stage, the analyte preparation stage and the analyte detection stage, wherein the loop thermosyphon is thermally coupled to a different stage than the second loop thermosyphon.

11. The instrument of claim 10, in which the analyte preparation stage comprises a torch, an induction device and a radio frequency generator electrically coupled to the induction device, in which the torch is configured to receive a section of the induction device and provide radio frequency energy into the section of the torch to sustain a plasma in the section of the torch, in which the loop thermosyphon is thermally coupled to a transistor of the radio frequency generator, and in which the second loop thermosyphon is thermally coupled to a pump present in the analyte detection stage.

12. The instrument of claim 10, in which the analyte preparation stage comprises a torch, an induction device and a radio frequency generator electrically coupled to the induction device, in which the torch is configured to receive a section of the induction device and provide radio frequency energy into the section of the torch to sustain a plasma in the section of the torch, in which the loop thermosyphon is thermally coupled to a transistor of the radio frequency generator, and in which the second loop thermosyphon is thermally coupled to an interface present between the torch and the analyte detection stage.

13. The instrument of claim 12, in which the second loop thermosyphon thermally couples to the interface through a first plate and a second plate.

14. The instrument of claim 13, in which the second plate comprises a groove to receive an evaporator loop of the loop thermosyphon and the first plate couples to the second plate to sandwich the evaporator loop between the first plate and the second plate, wherein the second plate couples to the interface.

15. The instrument of claim 10, in which the analyte introduction stage comprises a nebulizer, the analyte preparation stage comprises a torch, an induction device and a radio frequency generator electrically coupled to the induction device, in which the torch is configured to receive a section of the induction device and provide radio frequency energy into the section of the torch to sustain a plasma in the section of the torch, in which the loop thermosyphon is thermally coupled to a transistor of the radio frequency generator, in which the nebulizer is fluidically coupled to the torch, in which the analyte detection stage comprises a mass spectrometer, in which the mass spectrometer is fluidically coupled to the torch, and wherein the second loop thermosyphon is thermally coupled to a pump present in the mass spectrometer.

16. The instrument of claim 10, further comprising a third loop thermosyphon thermally coupled to at least one of the analyte introduction stage, the analyte preparation stage and the analyte detection stage.

17. The instrument of claim 16, in which the third loop thermosyphon is thermally coupled to a same stage as the first loop thermosyphon or the second look thermosyphon.

18. The instrument of claim 16, in which the second loop thermosyphon thermally couples to the interface through a first plate and a second plate.

19. The instrument of claim 16, in which the analyte introduction stage comprises a nebulizer, the analyte preparation stage comprises a torch, an induction device and a radio frequency generator electrically coupled to the induction device, in which the torch is configured to receive a section of the induction device and provide radio frequency energy into the section of the torch to sustain a plasma in the section of the torch, in which the loop thermosyphon is thermally coupled to a transistor of the radio frequency generator, in which the nebulizer is fluidically coupled to the torch, in which the analyte detection stage comprises a mass spectrometer, in which the mass spectrometer is fluidically coupled to the torch, and wherein the second loop thermosyphon is thermally coupled to a pump present in the mass spectrometer.

20. The instrument of claim 16, in which the analyte introduction stage comprises a nebulizer, the analyte preparation stage comprises a torch, an induction device and a radio frequency generator electrically coupled to the induction device, in which the torch is configured to receive a section of the induction device and provide radio frequency energy into the section of the torch to sustain a plasma in the section of the torch, in which the loop thermosyphon is thermally coupled to a transistor of the radio frequency generator, in which the nebulizer is fluidically coupled to the torch, in which the analyte detection stage comprises a mass spectrometer, in which the mass spectrometer is fluidically coupled to the torch through an interface, wherein the second loop thermosyphon is thermally coupled to a pump present in the mass spectrometer, and wherein the third loop thermosyphon is thermally coupled to the interface.

21-128. (canceled)
